(19) United States
(12) Patent Application Publication
(10) Pub. No.: US 2024/0368414 A1
(43) Pub. Date: Nov. 7, 2024

(54) INK COMPOSITION AND DISPLAY DEVICE

(71) Applicant: Samsung Display Co., Ltd., Yongin-si (KR)

(72) Inventors: KYUNGSIG LEE, Yongin-si (KR); Joon-Hyung KIM, Yongin-si (KR); JUO NAM, Yongin-si (KR); KAWON PAK, Yongin-si (KR); SEUNGHEE JANG, Yongin-si (KR); JAEBOK CHANG, Yongin-si (KR)

(73) Assignee: Samsung Display Co., Ltd., Yongin-si (KR)

(21) Appl. No.: 18/651,807

(22) Filed: May 1, 2024

(30) Foreign Application Priority Data
May 2, 2023 (KR) 10-2023-0057277

(51) Int. Cl. C09D 11/03; C09D 11/101; C09D 11/50; C09K 11/06; H10K 59/38

(52) U.S. Cl. CPC C09D 11/03; C09D 11/101; C09D 11/50; C09K 11/06; H10K 59/38

(57) ABSTRACT

Embodiments provide an ink composition and a display device. The ink composition includes a quantum dot, a first monomer that is an acrylate-based monomer, a second monomer, a scatterer, and an initiator. The second monomer is represented by Formula 1 or Formula 1-A, which are explained in the specification:

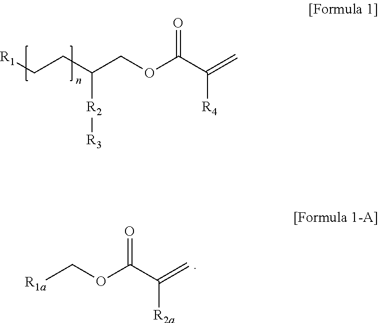

### CROSS-REFERENCE TO RELATED APPLICATION(S)

This application claims priority to and benefits of Korean Patent Application No. 10-2023-0057277 under 35 U.S.C. § 119, filed on May 2, 2023, in the Korean Intellectual Property Office, the entire contents of which are incorporated herein by reference.

### BACKGROUND

### 1. Technical Field

The disclosure relates to an ink composition for forming a light control layer included in a display device, and a display device having improved reliability.

### 2. Description of the Related Art

Various display devices used for multimedia apparatuses such as a television, a mobile phone, a tablet computer, a navigation system, and a game console are being developed. Such a display device uses a display element, which achieves a display by causing a light-emitting material containing an organic compound to emit light.

The display device may include a light control layer that controls light emitted from a display panel. The light control layer may be produced from a composition including a color conversion material and a scatterer.

During a process of forming the light control layer, the color conversion materials included in the composition may deteriorate, resulting in a decrease in photoconversion efficiency. Therefore, there is a demand for developing an ink composition capable of maintaining a photoconversion efficiency.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides an ink composition having excellent photoconversion efficiency.

The disclosure also provides a display device having improved display quality and reliability.

An embodiment provides an ink composition which may include a quantum dot, a first monomer that is an acrylate-based monomer, a second monomer represented by Formula 1 or Formula 1-A, a scatterer, and an initiator:

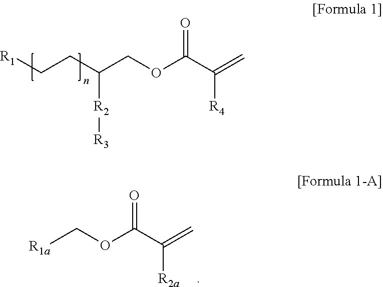

In Formula 1, R₁ may be an acrylate group or a group represented by one of Formulas 2 to 4, R₂ may be a direct linkage or a substituted or unsubstituted divalent oxy group, R₃ may be a hydrogen atom or a group represented by one of Formulas 2 to 4, and R₄ may be a hydrogen atom or a methyl group. In Formula 1, n may be an integer from 0 to 10, and one of R₁ and R₃ may be a group represented by one of Formulas 2 to 4. In Formula 1-A, R₁ₐ may be a group represented by one of Formulas 2 to 4, and R₂ₐ may be a hydrogen atom or a methyl group:

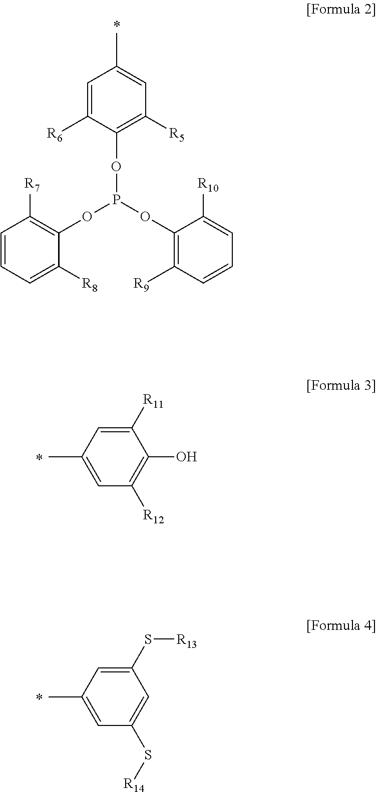

In Formulas 2 and 3, R₅ to R₁₂ may each independently be a substituted or unsubstituted alkyl group having 1 to 10 carbon atoms. In Formula 4, R₁₃ and R₁₄ may each independently be a substituted or unsubstituted alkyl group having 1 to 10 carbon atoms or a substituted or unsubstituted aryl group having 3 to 10 ring-forming carbon atoms.

In an embodiment, R₅ to R₁₀ may each independently be a substituted or unsubstituted t-butyl group, R₁₁ and R₁₂ may each independently be a substituted or unsubstituted methyl group or a substituted or unsubstituted t-butyl group, and R₁₃ and R₁₄ may each independently be a substituted or unsubstituted n-butyl group.

In an embodiment, the second monomer represented by Formula 1 may be represented by Formula 1-1 or Formula 1-2:

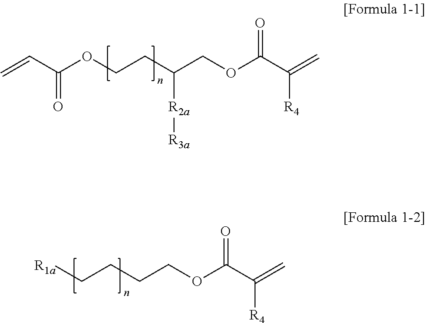

In Formula 1-1, R₂ₐ may be a direct linkage or a substituted or unsubstituted divalent alkyloxy group having 1 to 10 carbon atoms, and R₃ₐ may be a group represented by one of Formulas 2 to 4. In Formula 1-2, R₁ₐ may be a group represented by one of Formulas 2 to 4. In Formulas 1-1 and 1-2, R₄ and n may each be the same as defined in Formula 1.

In an embodiment, the second monomer may include at least one compound selected from Compound Group 1:

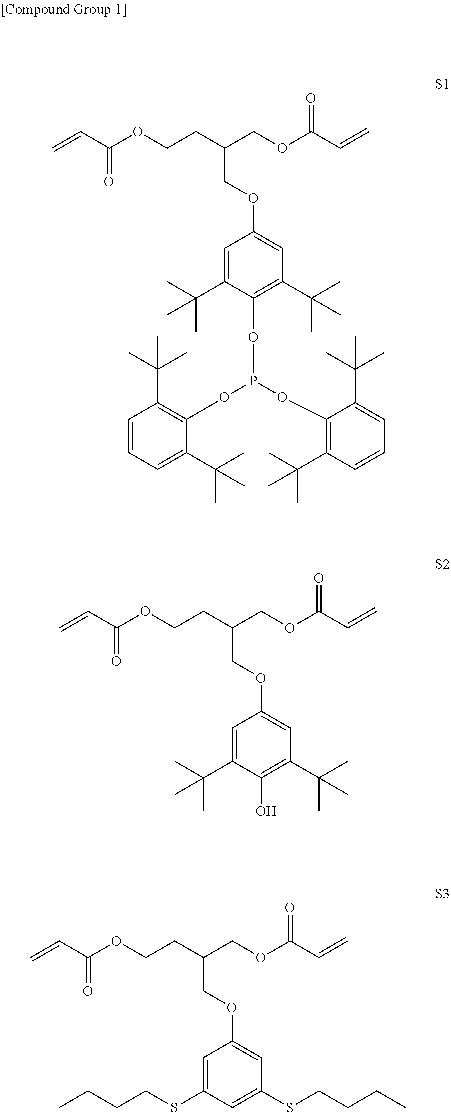

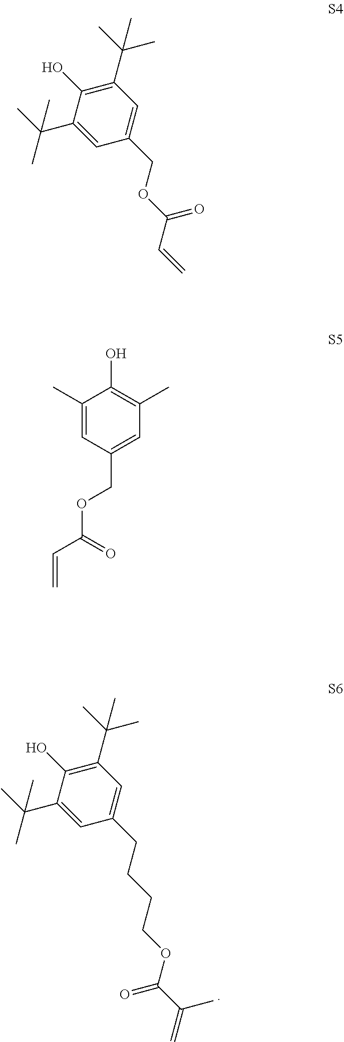

In an embodiment, an amount of the second monomer may be in a range of about 1 wt % to about 20 wt %, with respect to a total weight of the ink composition.

In an embodiment, an amount of the quantum dot may be in a range of about 30 wt % to about 50 wt %, with respect to a total weight of the ink composition.

In an embodiment, the quantum dot may include a core, and a shell covering the core.

In an embodiment, the core may include InP.

In an embodiment, the quantum dot further may include a ligand bound to a surface of the quantum dot.

In an embodiment, the ligand may include a thiol group (—SH) or a carboxylic acid group (—COOH).

In an embodiment, the first monomer may include 1,6-hexanediol diacrylate.

In an embodiment, the scatterer may include at least one of TiO₂, Al₂O₃, SiO₂, ZnO, ZrO₂, BaTiO₃, Ta₂O₅, Ti₃O₅, ITO, IZO, ATO, ZnO—Al, Nb₂O₃, SnO, and MgO.

An embodiment provides a display device which may include a circuit element layer, a display element layer disposed on the circuit element layer, and a light control layer disposed on the display element layer and including a first light control part, a second light control part, and a third light control part that are spaced apart in a direction perpendicular to a thickness direction. The first light control part and the second light control part may each include a quantum dot, a first monomer, a second monomer, and a scatterer; the third light control part may include the first monomer and the scatterer; and in the second monomer, a phosphorus-based antioxidant, a phenol-based antioxidant, or a sulfur-based antioxidant may be bound to an acrylate-based monomer via a covalent bond.

In an embodiment, the first monomer may be an acrylate-based monomer.

In an embodiment, the second monomer may be represented by Formula 1, which is described herein.

In an embodiment, the second monomer may be represented by Formula 1-1 or Formula 1-2, which are described herein.

In an embodiment, the second monomer may include at least one compound selected from Compound Group 1, which is described herein.

In an embodiment, the display device may further include a color filter layer disposed on the light control layer.

In an embodiment, the color filter layer may include a first filter, a second filter, and a third filter that respectively corresponds to the first light control part, the second light control part, and the third light control part.

In an embodiment, the first light control part, the second light control part, and the third light control part may each be parallel to the direction perpendicular to a thickness direction, the first filter, the second filter, and the third filter may each be arranged in the direction perpendicular to a thickness direction, and on a cross-section arranged in the thickness direction, a minimum width of each of the first to third light control parts may be substantially the same as a minimum width of each of the first to third filters.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is an enlarged schematic plan view of a portion of a display device according to an embodiment;

FIG. 3 is a schematic cross-sectional view of a display device, taken along line I-I′ in FIG. 2;

FIGS. 4A and 4B are each a schematic cross-sectional view of a light-emitting element according to an embodiment;

FIGS. 5A and 5B are each a schematic cross-sectional view of a structure of a quantum dot according to an embodiment;

FIG. 6 is a schematic cross-sectional view of an ink composition according to an embodiment; and

FIGS. 7A to 7C are each a graph showing photoconversion efficiency maintenance rate of ink compositions according to the Examples and the Comparative Examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for case of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

In the specification, the expressions used in the singular such as “a,” “an,” and “the,” are intended to include the plural forms as well, unless the context clearly indicates otherwise.

In the specification, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amine group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

Hereinafter, an ink composition and a display device according to an embodiment will be described with reference to the drawings.

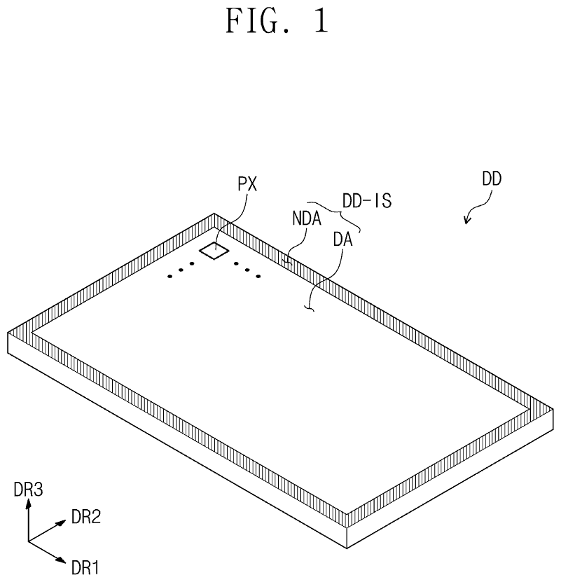

FIG. 1 is a schematic perspective view of a display device according to an embodiment.

Referring to FIG. 1, a display device DD according to an embodiment may be a device activated in response to an electrical signal. For example, the display device DD may be a large-sized device such as a television, a monitor, or an outdoor billboard. As another example, the display device DD may be a small- or medium-sized device such as a personal computer, a laptop computer, a personal digital assistant, a car navigation unit, a game console, a tablet computer, or a camera. These examples are merely presented for illustrative purposes, and the display device DD may be in the form of other electronic devices without deviating from the embodiments.

The display device DD may display an image (or a video) through a display surface DD-IS. The display surface DD-IS may be parallel to a surface defined by a first direction DR1 and a second direction DR2. The display surface DD-IS may include a display region DA and a non-display region NDA.

A pixel PX may be disposed in the display region DA, and may not be disposed in the non-display region NDA. The non-display region NDA may be defined along an edge of the display surface DD-IS. The non-display region NDA may surround the display region DA. However, embodiments are not limited thereto. For example, the non-display region NDA may be omitted, or the non-display region NDA may be disposed on only one side of the display region DA.

The display device DD having a flat display surface DD-IS is illustrated in FIG. 1, but embodiments are not limited thereto. The display device DD may also include a curved display surface or a stereoscopic display surface. For example, a stereoscopic display surface may include multiple display regions indicating different directions.

A thickness direction of the display device DD may be parallel to a third direction DR3, which is a normal direction of a plane defined by the first direction DR1 and the second direction DR2. In the specification, the directions that are indicated by the first to third directions DR1, DR2, and DR3 may be relative terms, and may thus be changed into other directions.

In the specification, a top surface (or front surface) and a bottom surface (or rear surface) of each of the members configuring the display device DD may be defined with respect to the third direction DR3. For example, a surface relatively more adjacent to the display surface DD-IS among two surfaces which face each other in the third direction DR3 in a member may be defined as a front surface (or a top surface), and a surface relatively further spaced apart in the third direction DR3 from the display surface DD-IS may be defined as a rear surface (or a bottom surface). In the specification, an upper part and a lower part may be defined with respect to the third direction DR3, the upper part may be defined as a part arranged in a direction proximal to display surface DD-IS in the third direction DR3, and the lower part may be defined as a part arranged in a direction distal from the display surface DD-IS in the third direction DR3.

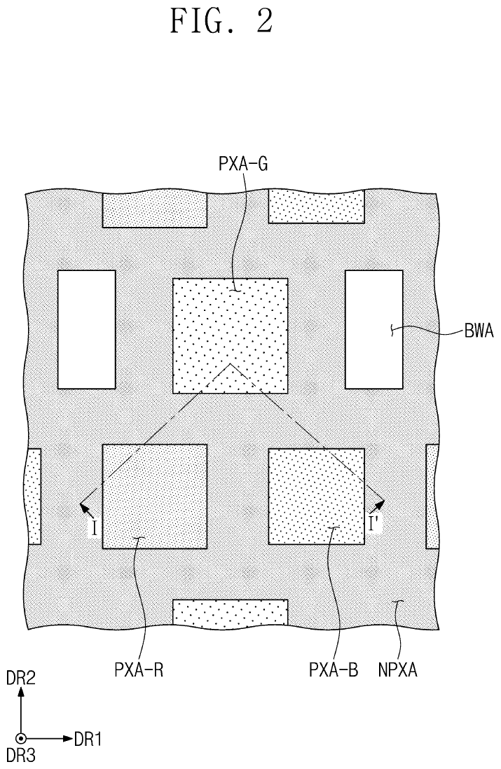

FIG. 2 is an enlarged schematic plan view of a portion of the display device DD according to an embodiment. FIG. 2 is a plan view including three pixel regions PXA-R, PXA-G, and PXA-B, and a bank well region BWA adjacent thereto. The three pixel regions PXA-R, PXA-G, and PXA-B illustrated in FIG. 2 corresponds to a pixel PX (see FIG. 1) and may be repeatedly disposed on the entire display region DA (see FIG. 1).

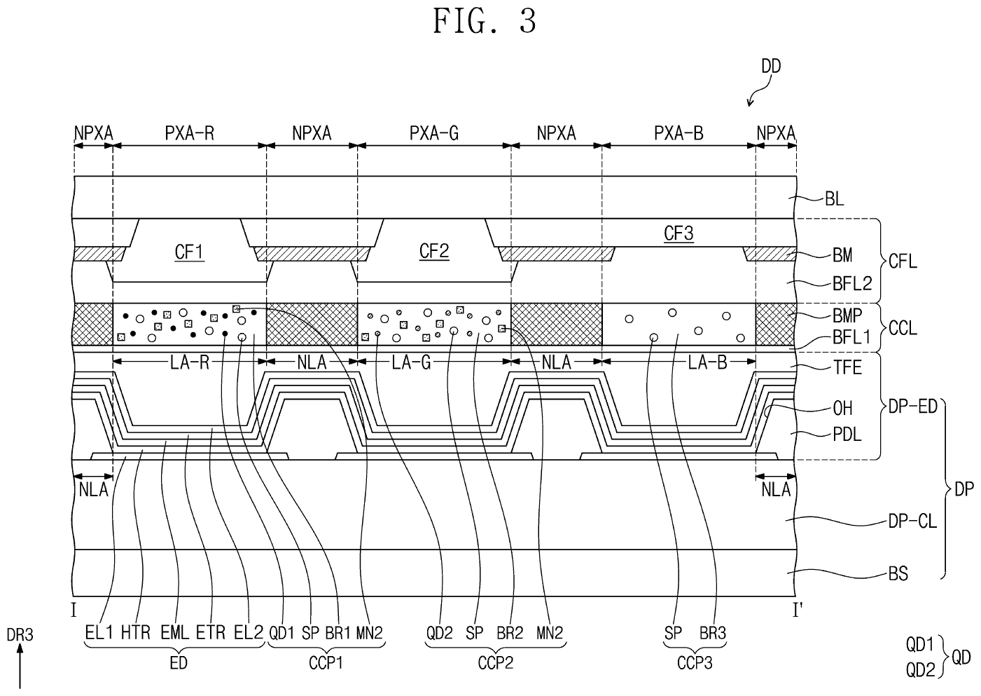

A peripheral region NPXA may be disposed around each of the first to third pixel regions PXA-R, PXA-G, and PXA-B. The peripheral region NPXA may define boundaries of the first to third pixel regions PXA-R, PXA-G, and PXA-B. The peripheral region NPXA may surround the first to third pixel regions PXA-R, PXA-B, and PXA-G. In the peripheral region NPXA, a structure for preventing color mixing of the first to third pixel regions PXA-R, PXA-G, and PXA-B, for example, a pixel definition film PDL (see FIG. 3) or division patterns BMP (see FIG. 3) or the like may be disposed therein.

The first to third pixel regions PXA-R, PXA-G, and PXA-B, which may have a same shape in a plan view, and may have different areas in the plan view, are illustrated in FIG. 2, but embodiments are not limited thereto. At least two of the first to third pixel regions PXA-R, PXA-G, and PXA-B may have a same area. The areas of the first to third pixel regions PXA-R, PXA-G, and PXA-B may be determined according to the color of emitted light. A pixel region emitting red light among primary colors may have a largest area and a pixel region emitting blue light may have a smallest area.

Although FIG. 2 illustrates each of the first to third pixel regions PXA-R, PXA-G, and PXA-B as having a rectangular shape in a plan view, the shape of each of the first to third pixel regions PXA-R, PXA-G, and PXA-B are not limited thereto. The first to third pixel regions PXA-R, PXA-G, and PXA-B may each have different polygonal shapes such as a rhombus or a pentagon in a plan view. In an embodiment, the first to third regions PXA-R, PXA-G, and PXA-B may each have a rectangular shape having rounded corner regions.

FIG. 2 illustrates that the second pixel region PXA-G is arranged in a first row, and the first pixel region PXA-R and the third pixel region PXA-B are arranged in a second row. However, this is only an example, and the arrangement of the first to third pixel regions PXA-R, PXA-G, and PXA-B may be variously modified. For example, the first to third pixel regions PXA-R, PXA-G, and PXA-B may be disposed in a same row.

One of the first to third pixel regions PXA-R, PXA-G, and PXA-B may emit first color light, another may emit second color light that is different from the first color light, and yet another may emit third color light that is different from the first color light and the second color light. In an embodiment, the third pixel region PXA-B may provide third color light corresponding to a portion of source light. For example, the first pixel region PXA-R may emit red light, the second pixel region PXA-G may emit green light, and the third pixel region PXA-B may transmit or emit blue light.

In the display region DA (see FIG. 1), a bank well region BWA may be defined. The bank well region BWA may be a region that prevents defects due to misplacement in a process of patterning light control parts CCP1, CCP2, and CCP3 that are included in a light control layer CCL (see FIG. 3), which will be described below. The bank well region BWA may be a region in which a portion of a division pattern BMP (see FIG. 3) is removed. FIG. 2 illustrates that two bank well regions BWA are formed to be adjacent to the second pixel region PXA-G. However, embodiments are not limited thereto, and the shape and arrangement of the bank well region BWA may be variously changed.

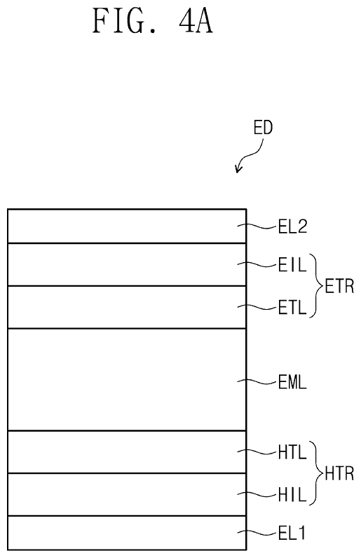

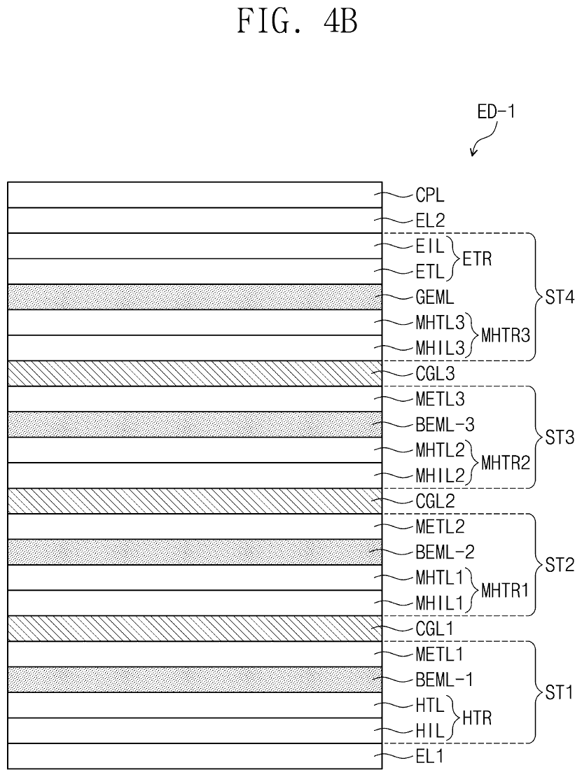

FIG. 3 is a schematic cross-sectional view of a display device according to an embodiment. FIG. 3 is a schematic cross-sectional view taken along line I-I′ of FIG. 2. FIGS. 4A and 4B are each a schematic cross-sectional view of a light-emitting element included in a display device according to an embodiment.

Referring to FIG. 3, a display device DD according to an embodiment may include a display panel DP, a light control layer CCL disposed on the display panel DP, and a color filter layer CFL disposed on the light control layer CCL.

The display panel DP may include a base substrate BS, a circuit element layer DP-CL disposed on the base substrate BS, and a display element layer DP-ED disposed on the circuit element layer DP-CL. In the specification, the base substrate BS, the circuit element layer DP-CL, and the display element layer DP-ED may be collectively referred to as a lower panel, a lower display substrate, or a display member.

The base substrate BS may provide a base surface on which a component included in the circuit element layer DP-CL is disposed. In an embodiment, the base substrate BS may be a glass substrate, a metal substrate, a polymer substrate, etc. However, embodiments are not limited thereto, and the base substrate BS may include an inorganic layer, an organic layer, a functional layer, or a composite material layer.

The base substrate BS may have a multilayer structure. For example, the base substrate BS may have a three-layer structure of a polymer resin layer, a barrier layer, and a polymer resin layer. For example, the polymer resin layer may include a polyimide-based resin. In an embodiment, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and/or a perylene-based resin. In the specification, the term “x-based” resin means that the resin contains a functional group of an “x-” group. The barrier layer may be an inorganic layer containing an inorganic material.

The circuit element layer DP-CL may be disposed on the base substrate BS. The circuit element layer DP-CL may include transistors (not illustrated). The transistors (not illustrated) may each include a control electrode, an input electrode, and an output electrode. For example, the circuit element layer DP-CL may include a switching transistor and a driving transistor for driving a light-emitting element ED of the display element layer DP-ED.

The display element layer DP-ED may include the light-emitting element ED as a display element. The light-emitting element ED may generate the above-described source light. Referring to FIGS. 3 and 4A, the light-emitting element ED may include a first electrode EL1, a hole transport region HTR, a light-emitting layer EML, an electron transport region ETR, and a second electrode EL2. The hole transport region HTR may include at least one of a hole injection layer HIL, a hole transport layer HTL, and an electron blocking layer (not illustrated). The electron transport region ETR may include at least one of an electron injection layer EIL, an electron transport layer ETL, and a hole blocking layer (not illustrated).

In an embodiment, the display element layer DP-ED may include an organic light-emitting diode as a light-emitting element ED. In an embodiment, the light-emitting element ED may include a quantum dot light-emitting diode. For example, a light-emitting layer EML included in the light-emitting element ED may include an organic light-emitting material as a light-emitting material, or the light-emitting layer EML may include a quantum dot as a light-emitting material. In an embodiment, the display element layer DP-ED may include an ultra-small light-emitting element as a light-emitting element. The ultra-small light-emitting element may include, for example, a micro LED element and/or a nano LED element. The ultra-small light-emitting element may have a micro- or nano-scale size, and may include an active layer disposed between multiple semiconductor layers.

The display element layer DP-ED may include a pixel definition film PDL. For example, the pixel definition film PDL may be an organic layer. An opening OH may be defined in the pixel definition film PDL. The opening OH of the pixel definition film PDL may expose at least a portion of the first electrode EL1. In an embodiment, first to third light-emitting regions LA-R, LA-G and LA-B may be defined by the opening OH. A non-emitting region NLA may be disposed around each of first to third light-emitting regions LA-R, LA-G, and LA-B. The non-emitting region NLA may define boundaries of the first to third light-emitting regions LA-R, LA-G, and LA-B. The non-emitting region NLA may overlap the pixel definition films PDL.

FIG. 3 illustrates an embodiment in which a hole transport region HTR, a light-emitting layer EML, an electron transport region ETR, and a second electrode EL2 are each provided as common layers to the first to third pixel regions PXA-R, PXA-G, and PXA-B. Each of the hole transport region HTR, the light-emitting layer EML, the electron transport region ETR, and the second electrode EL2 overlapping the first to third pixel regions PXA-R, PXA-G, and PXA-B may have an integrated shape. However, embodiments are not limited thereto, and at least one of the hole transport region HTR, the light-emitting layer EML, and the electron transport region ETR may be separately formed in each of the first to third pixel regions PXA-R, PXA-G, and PXA-B. In an embodiment, the hole transport region HTR, the light-emitting layer EML, the electron transport region ETR, and the like may be patterned in the opening OH, and may be separately formed in each of the first to third pixel regions PXA-R, PXA-G, and PXA-B. For example, in an embodiment, the hole transport region HTR, the light-emitting layer EML, the electron transport region ETR, and the like of the light-emitting element ED may be provided by being patterned through an ink-jet printing process.

Referring to FIGS. 3 and 4A, the light-emitting element ED includes a first electrode EL1, a second electrode EL2 facing the first electrode EL1, and functional layers disposed between the first electrode EL1 and the second electrode EL2 and including the light-emitting layer EML.

The functional layers may include a hole transport region HTR disposed between the first electrode EL1 and the light-emitting layer EML and an electron transport region ETR disposed between the light-emitting layer EML and the second electrode EL2. In an embodiment, a capping layer CPL (see FIG. 4B) may be further disposed on the second electrode EL2.

The hole transport region HTR and the electron transport region ETR may each include sub-functional layers. For example, the hole transport region HTR may include a hole injection layer HIL and a hole transport layer HTL as sub-functional layers, and the electron transport region ETR may include an electron injection layer EIL and an electron transport layer ETL as sub-functional layers. However, embodiments are not limited thereto, and the hole transport region HTR may further include an electron blocking layer (not illustrated), etc., as a sub-functional layer, the electron transport region ETR may further include a hole blocking layer (not illustrated), etc., as a sub-functional layer.

In a light-emitting element ED according to an embodiment, the first electrode EL1 may have conductivity. The first electrode EL1 may be formed of a metal alloy or a conductive compound. The first electrode EL1 may be an anode. The first electrode EL1 may be a pixel electrode.

In a light-emitting element ED according to an embodiment, the first electrode EL1 may be a reflective electrode, but embodiments are not limited thereto. For example, the first electrode EL1 may be a transmissive electrode or a transflective electrode. When the first electrode EL1 is a transmissive electrode or a transflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In another embodiment, the first electrode EL1 may have a multilayer structure including a reflective film, or a transflective film, formed of the above-listed materials, and a transparent conductive film formed of indium tin oxide (ITO), indium zinc oxide (IZO), zinc oxide (ZnO), indium tin zinc oxide (ITZO), or the like. For example, the first electrode EL1 may be a metal film having a structure in which ITO/Ag/ITO metal films are stacked.

The hole transport region HTR may be provided on the first electrode EL1. The hole transport region HTR may include a hole injection layer HIL, a hole transport layer HTL, etc. The hole transport region HTR may further include at least one of a hole buffer layer (not illustrated) or an electron blocking layer (not illustrated), in addition to the hole injection layer HIL and the hole transport layer HTL. The hole buffer layer (not illustrated) may compensate for a resonance distance according to a wavelength of light emitted from the light-emitting layer EML, thereby increasing light emission efficiency. A material that may be included in the hole transport region HTR may be used as a material included in the hole buffer layer (not illustrated. The electron blocking layer (not illustrated) may prevent the injection of electrons from the electron transport region ETR to the hole transport region HTR.

The hole transport region HTR may be a layer consisting of a single material, a layer including different materials, or a structure including multiple layers including different materials.

For example, the hole transport layer HTR may have a single-layer structure formed of different materials. In embodiments, the hole transport layer HTR may have a structure in which a hole injection layer HIL/hole transport layer HTL, a hole injection layer HIL/hole transport layer HTL/hole buffer layer (not illustrated), a hole injection layer HIL/hole buffer layer (not illustrated), a hole transport layer HTL/hole buffer layer (not illustrated), or a hole injection layer HIL/hole transport layer HTL/electron blocking layer (not illustrated) are stacked in its respective stated order from the first electrode EL1, but embodiments are not limited thereto.

The hole transport region HTR may be formed by various methods such as a vacuum deposition method, a spin coating method, a cast method, a LB (Langmuir-Blodgett) method, an inkjet printing method, a laser printing method, and a laser induced thermal imaging (LITI) method.

The hole injection layer HIL may include, for example, a phthalocyanine compound such as copper phthalocyanine, N,N′-diphenyl-N,N′-bis[4-(phenyl-m-tolyl-amino)-phenyl]-biphenyl-4,4′-diamine (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), polyether ketone containing triphenylamine (TRAPEK), 4-isopropyl-4′-methyldiphenyliodonium[tetrakis(pentafluorophenyl)borate], dipyrazino[2,3-f: 2′,3′-h] quinoxaline-2,3,6,7,10,11-hexacarbonitrile (HAT-CN), etc.

The hole transport layer HTL may include materials of the related art. For example, the hole transport layer HTL may further include a carbazole derivative such as N-phenyl carbazole and polyvinyl carbazole, a fluorene derivative, a triphenylamine-based derivative such as N,N′-bis(3-methylphenyl)-N,N′-diphenyl-[1,1′-biphenyl]-4,4′-diamine (TPD), 4,4′,4″-tris(N-carbazolyl)triphenylamine (TCTA), N,N′-di(naphthalene-1-yl)-N,N′-diphenyl-benzidine (NPD), 4,4′-Cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and the like.

The hole transport region HTR may have a thickness in a range of about 5 nm to about 1500 nm. For example, the hole transport region HTR may have a thickness in a range of about 10 nm to about 500 nm. For example, the hole injection layer HIL may have a thickness in a range of about 3 nm to about 100 nm. For example, the hole transport layer HTL may have a thickness in a range of about 3 nm to about 100 nm. For example, the electron blocking layer (not illustrated) may have a thickness in a range of about 1 nm to about 100 nm. When the thicknesses of the hole transport region HTR, the hole injection layer HIL, the hole transport layer HTL and the electron blocking layer (not illustrated) fall within the above-mentioned ranges, satisfactory hole transport characteristics may be obtained without a substantial increase in a driving voltage.

The light-emitting layer EML is provided on the hole transport region HTR. In an embodiment, the light-emitting layer EML may be provided as a common layer to entirely overlap the first to third light-emitting regions LA-R, LA-G, and LA-B and the pixel definition films PDL, which separates the first to third light-emitting regions LA-R, LA-G, and LA-B. In an embodiment, the light-emitting layer EML may emit blue light. The light-emitting layer EML may overlap the entirety of both the hole transport region HTR and electron transport region ETR.

However, embodiments are not limited thereto. For example, in another embodiment, the light-emitting layer EML may be disposed within the opening OH. For example, light-emitting layers EML may be separately formed to respectively correspond to the first to third light-emitting regions LA-R, LA-G, and LA-B, which are separated by the pixel definition films PDL. The light-emitting layers EML that are separately formed so as to respectively correspond to the first to third light-emitting regions LA-R, LA-G, and LA-B may emit third light, which is source light. For example, all of the light-emitting layer EML may emit blue light. The blue light emitted from the light-emitting layer EML may include light having a wavelength in a range of about 410 nm to about 480 nm. A light-emitting spectrum of the blue light may have a maximum peak wavelength in a range of about 440 nm to about 460 nm. However, embodiments are not limited thereto, and the light-emitting layer EML may emit light in different wavelength ranges.

The light-emitting layer EML may be a layer consisting of a single material, a layer including different materials, or a structure including multiple layers including different materials.

The light-emitting layer EML may include a fluorescent or phosphorescent material. In a light-emitting element ED according to an embodiment, the light-emitting layer EML may include, as a light-emitting material, an organic light-emitting material, an organometallic complex, a quantum dot, or the like. FIGS. 3 and 4A illustrate the light-emitting element ED including one light-emitting layer EML, but embodiments are not limited thereto. For example, in an embodiment, the light-emitting element ED may include a stack of multiple light-emitting structures, each including at least one light-emitting layer EML.

In contrast to the light-emitting element ED illustrated in FIGS. 3 and 4A, FIG. 4B is different at least in that it illustrates a light-emitting element ED-1 including a stack of light-emitting structures ST1, ST2, ST3, and ST4.

Referring to FIG. 4B, the light-emitting element ED-1 according to an embodiment may include a first electrode EL1, a second electrode EL2 facing the first electrode EL1, and first to fourth light-emitting structures ST1, ST2, ST3, and ST4 disposed between the first electrode EL1 and the second electrode EL2. FIG. 4B illustrates an embodiment of a light-emitting element ED-1 that includes four light-emitting structures but the number of light-emitting structures included in the light-emitting element ED-1 may be less than four or more than four.

The light-emitting element ED-1 may include first to third charge generation layers CGL1, CGL2, and CGL3 that are each disposed between adjacent light-emitting structures among the first to fourth light-emitting structures ST1, ST2, ST3, and ST4.

When a voltage is applied to each of the first to third charge generation layers CGL1, CGL2, and CGL3, a complex may be formed through an oxidation-reduction reaction to generate charges (for example, electrons and holes). The first to third charge generation layers CGL1, CGL2, and CGL3 may provide the generated charges to adjacent light-emitting structures among the first to fourth light-emitting structures ST1, ST2, ST3, and ST4. The first to third charge generation layers CGL1, CGL2, and CGL3 may increase (for example, double) the efficiency of a current generated in adjacent light-emitting structures among the first to fourth light-emitting structures ST1, ST2, ST3, and ST4, and may control the balance of charges between adjacent light-emitting structures among the first to fourth light-emitting structures ST1, ST2, ST3, and ST4.

The first to third charge generation layers CGL1, CGL2, and CGL3 may each include an n-type layer and a p-type layer. The first to third charge generation layers CGL1, CGL2, and CGL3 may each have a structure in which the n-type layer and the p-type layer are joined to each other. However, embodiments are not limited thereto, and the first to third charge generation layers CGL1, CGL2, and CGL3 may each independently include at least one of an n-type layer and a p-type layer. The n-type layer may provide electrons to an adjacent light-emitting structure. The n-type layer may include a base material that is doped with an n-type dopant. The p-type layer may provide holes to an adjacent light-emitting structure.

In an embodiment, the first to third charge generation layers CGL1, CGL2, and CGL3 may each independently have a thickness in a range of about 1 Å to about 300 Å. For example, the first to third charge generation layers CGL1, CGL2, and CGL3 may each have a thickness of about 165 Å. A concentration of the n-type dopant of the first to third charge generation layers CGL1, CGL2, and CGL3 may each independently be in a range of about 0.1% to about 3%. For example, the concentration of the n-type dopant of the first to third charge generation layers CGL1, CGL2, and CGL3 may each independently be less than or equal to about 1%. When the concentration of the n-type dopant is less than about 0.1%, the effect of the first to third charge generation layers CGL1, CGL2, and CGL3 that control the balance of charges may not be readily achieved. When the concentration of the n-type dopant is greater than about 3%, the light-emitting efficiency of a light-emitting element ED-1 may be lowered.

In an embodiment, the first to third charge generation layers CGL1, CGL2, and CGL3 may each include a charge generation compound formed of an arylamine-based organic compound, a metal, a metal oxide, a carbide, a fluoride, or a mixture thereof. For example, the arylamine-based organic compound may include α-NPD, 2-TNATA, TDATA, MTDATA, spiro-TAD, or spiro-NPB. The metal may include cesium (Cs), molybdenum (Mo), vanadium (V), titanium (Ti), tungsten (W), barium (Ba), or lithium (Li). The metal oxide, carbide, and fluoride may include Re₂O₇, MoO₃, V₂O₅, WO₃, TiO₂, Cs₂CO₃, BaF, LiF, or CsF. However, the materials of the first to third charge generation layers CGL1, CGL2, and CGL3 are not limited thereto.

The first to fourth light-emitting structures ST1, ST2, ST3, and ST4 may each include a light-emitting layer. The first light-emitting structure ST1 may include a first light-emitting layer BEML-1, the second light-emitting structure ST2 may include a second light-emitting layer BEML-2, the third light-emitting structure ST3 may include a third light-emitting layer BEML-3, and the fourth light-emitting structure ST4 may include a fourth light-emitting layer GEML. Some of the light-emitting layers included in the first to fourth light-emitting structure ST1, ST2, ST3, and ST4 may emit light having substantially a same color, and some may emit light having different colors.

In an embodiment, the first to third light-emitting layers BEML-1, BEML-2, and BEML-3 of the first to third light-emitting structures ST1, ST2, and ST3 may emit first color light, which may be substantially the same. For example, the first color light may be blue light, which is the source light. The wavelength of light emitted from the first to third light-emitting layers BEML-1, BEML-2, and BEML-3 may each independently be in a range of about 420 nm to about 480 nm.

The fourth light-emitting layer GEML of the fourth light-emitting structure ST4 may emit second color light that is different from the first color light. For example, the second color light may be green light. The wavelength of light emitted from the fourth light-emitting layer GEML may be in a range of about 520 nm to about 600 nm.

At least some of the first to fourth light-emitting layers BEML-1, BEML-2, BEML-3, and GEML may have a two-layer structure that includes different host materials. For example, one layer of the two-layer structure may include a hole transporting host material, and the other layer may include an electron transporting host material. The electron transporting host material may include an electron transporting moiety in a molecular structure thereof.

The first light-emitting structure ST1 may include a hole transport region HTR which transports, to the first light-emitting layer BEML-1, holes provided from the first electrode EL1, and a first intermediate electron transport region METL1, which transports, to the first light-emitting layer BEML-1, electrons generated from the first charge generation layer CGL1.

The hole transport region HTR may include a hole injection layer HIL disposed on the first electrode EL1, and a hole transport layer HTL disposed on the hole injection layer HIL. However, embodiments are not limited thereto, and the hole transport region HTR may further include at least one of a hole buffer layer, a light-emitting auxiliary layer, and an electron blocking layer. The hole transport layer HTL and the hole buffer layer may increase light-emitting efficiency by compensating for a resonance distance according to a wavelength of light emitted from the light-emitting layer. The electron blocking layer may block electron injection from the first intermediate electron transport region METL1 to the hole transport region HTR.

The first intermediate electron transport region METL1 may include a first intermediate electron transport layer disposed on the first light-emitting layer BEML-1. However, embodiments are not limited thereto, and the first intermediate electron transport region METL1 may further include at least one of an electron buffer layer and a hole blocking layer.

The second light-emitting structure ST2 may include a first intermediate hole transport region MHTR1, which transports, to the second light-emitting layer BEML-2, holes generated from the first charge generation layer CGL1, and a second intermediate electron transport region METL2, which transports, to the second light-emitting layer BEML-2, electrons provided from the second charge generation layer CGL2.

The first intermediate hole transport region MHTR1 may include a first intermediate hole transport layer MHTL1 disposed on the first charge generation layer CGL1. The first intermediate hole transport region MHTR1 may further include at least one of a hole buffer layer, a light-emitting auxiliary layer, and an electron blocking layer disposed on the first intermediate hole transport layer MHTL1. The first intermediate hole transport region MHTR1 may further include a first intermediate hole injection layer MHIL1 disposed on the first charge generation layer CGL1. The first intermediate hole injection layer MHIL1 may be disposed between the first charge generation layer CGL1 and the first intermediate hole transport layer MHTL1. Although not shown in FIG. 4B, in an embodiment, the first intermediate hole injection layer MHIL1 may be omitted.

The second intermediate electron transport region METL2 may include a second intermediate electron transport layer disposed on the second light-emitting layer BEML-2. However, embodiments are not limited thereto, and the second intermediate electron transport region METL2 may further include at least one of an electron buffer layer and a hole blocking layer disposed between the second intermediate electron transport layer and the second light-emitting layer BEML-2.

The third light-emitting structure ST3 may include a second intermediate hole transport region MHTR2, which transports, to the third light-emitting layer BEML-3, holes generated from the second charge generation layer CGL2, and a third intermediate electron transport region METL3, which transports, to the third light-emitting layer BEML-3, electrons provided from the third charge generation layer CGL3.

The second intermediate hole transport region MHTR2 may include a second intermediate hole transport layer MHTL2 disposed on the second charge generation layer CGL2. However, embodiments are not limited thereto, and the second intermediate hole transport region MHTR2 may further include at least one of a hole buffer layer, a light-emitting auxiliary layer, and an electron blocking layer disposed on the second intermediate hole transport layer MHTL2. The second intermediate hole transport region MHTR2 may further include a second intermediate hole injection layer MHIL2 disposed on the second charge generation layer CGL2. The second intermediate hole injection layer MHIL2 may be disposed between the second charge generation layer CGL2 and the second intermediate hole transport layer MHTL2. Although not shown in FIG. 4B, in an embodiment, the second intermediate hole injection layer MHIL2 may be omitted.

The third intermediate electron transport region METL3 may include a third intermediate electron transport layer disposed on the third light-emitting layer BEML-3. However, embodiments are not limited thereto, and the third intermediate electron transport region METL3 may further include at least one of an electron buffer layer and a hole blocking layer disposed between the third intermediate electron transport layer and the third light-emitting layer BEML-3.

The fourth light-emitting structure ST4 may include a third intermediate hole transport region MHTR3, which transports, to the fourth light-emitting layer GEML, holes generated from the third charge generation layer CGL3, and an electron transport region ETR, which transports, to the fourth light-emitting layer GEML, electrons provided from the second electrode EL2.

The third intermediate hole transport region MHTR3 may include a third intermediate hole transport layer MHTL3 disposed on the third charge generation layer CGL3. However, embodiments are not limited thereto, and the third intermediate hole transport region MHTR3 may further include at least one of a hole buffer layer, a light-emitting auxiliary layer, and an electron blocking layer disposed on the third intermediate hole transport layer MHTL3. The third intermediate hole transport region MHTR3 may further include a third intermediate hole injection layer MHIL3 disposed on the third charge generation layer CGL3. The third intermediate hole injection layer MHIL3 may be disposed between the third charge generation layer CGL3 and the third intermediate hole transport layer MHTL3. Although not shown in FIG. 4B, in an embodiment, the third intermediate hole injection layer MHIL3 may be omitted.

The electron transport region ETR may include an electron transport layer ETL disposed on the fourth light-emitting layer GEML, and an electron injection layer EIL disposed on the electron transport layer ETL. However, embodiments are not limited thereto, and the electron transport region ETR may further include at least one of an electron buffer layer and a hole blocking layer disposed between the electron transport layer ETL and the fourth light-emitting layer GEML.

In an embodiment, the light-emitting element ED-1 may emit light in a direction from the first electrode EL1 to the second electrode EL2, and with respect to the direction in which the light is emitted, the hole transport region HTR may be disposed below the light-emitting structures ST1, ST2, ST3, and ST4, and the electron transport region ETR may be disposed above the light-emitting structures ST1, ST2, ST3, and ST4. However, embodiments are not limited thereto, and with respect to the light emission direction, the light-emitting element ED-1 may have an inverted structure, in which the electron transport region ETR is disposed below the light-emitting structures ST1, ST2, ST3, and ST4, and the hole transport region HTR is disposed above the light-emitting structures ST1, ST2, ST3 and ST4.

Referring again to FIGS. 3 and 4A, in the light-emitting element ED according to an embodiment, the electron transport region ETR is disposed on the light-emitting layer EML. The electron transport region ETR may include at least one of a hole blocking layer (not illustrated), an electron transport layer ETL, or an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer formed of an electron injection material and an electron transport material. In embodiment, the electron transport region ETR may have a single layer structure formed of different materials, or may have a structure in which an electron transport layer ETL/electron injection layer EIL, or a hole blocking layer (not illustrated)/electron transport layer ETL/electron injection layer EIL structure are stacked in its respective stated order from the light-emitting layer EML. However, embodiments are not limited thereto. The electron transport region ETR may have a thickness, for example, in a range of about 20 nm to about 150 nm.

The electron transport region ETR may be formed by various methods such as a vacuum deposition method, a spin coating method, a cast method, a LB (Langmuir-Blodgett) method, an inkjet printing method, a laser printing method, and a laser induced thermal imaging (LITI) method.

When the electron transport region ETR includes an electron transport layer ETL, the electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, bis[2-(diphenylphosphino)phenyl]ether oxide (DPEPO), 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl) anthracene (ADN), or a mixture thereof.

The electron transport layer ETL may have a thickness in a range of about 10 nm to about 100 nm. For example, the electron transport layer ETL may have a thickness in a range of about 15 nm to about 50 nm. When the thickness of the electron transport layer ETL falls within any of the above-mentioned ranges, satisfactory electron transport characteristics may be obtained without a substantial increase in driving voltage.

When the electron transport region ETR includes an electron injection layer EIL, the electron transport region ETR may include: a metal halide such as LiF, NaCl, CsF, RbCl, or RbI; a lanthanide metal such as Yb; a metal oxide such as Li₂O, and BaO; or lithium quinolate (Liq). However, embodiments are not limited thereto. The electron injection layer EIL may also be formed of a mixture of an electron transport material and an insulating organometallic salt. For example, the insulating organometallic salt may include a metal acetate, a metal benzoate, a metal acetoacetate, a metal acetylacetonate, or a metal stearate. The electron injection layer EIL may have a thickness in a range of about 0.1 nm to about 10 nm. For example, the electron injection layer EIL may have a thickness in a range of about 0.3 nm to about 9 nm. When the thickness of the electron injection layers EIL falls within any of the above-mentioned ranges, satisfactory electron injection characteristics may be obtained without a substantial increase in driving voltage.

As mentioned above, the electron transport region ETR may include a hole blocking layer (not illustrated). The hole blocking layer (not illustrated) may include, for example, at least one of 2,9-dimethyl-4,7-diphenyl-1,10-phenanthroline (BCP) or 4,7-diphenyl-1,10-phenanthroline (Bphen), but is not limited thereto.

The second electrode EL2 may be provided on the electron transport region ETR. The second electrode EL2 may be a common electrode or a cathode electrode. The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, a compound thereof (for example, AgYb, compounds of AgMg and MgYb depending on the contents, etc.) or a mixture thereof (for example, a mixture of Ag and Mg). In another embodiment, the second electrode EL2 may have a structure having multiple layers including a reflective film or a semipermeable film formed of the above materials, or a transparent conductive film formed of indium tin oxide (ITO), indium zinc oxide (IZO), zinc oxide (ZnO), indium tin zinc oxide (ITZO), or the like.

Although not shown in the drawings, the second electrode EL2 may be electrically connected to an auxiliary electrode. When the second electrode EL2 is electrically connected to the auxiliary electrode, resistance of the second electrode EL2 may be reduced.

Referring to FIG. 3, an encapsulation layer TFE may be disposed on the light-emitting element ED. For example, the encapsulation layer TFE may be disposed on the second electrode EL2 and may be disposed to fill the openings OH. When the light-emitting element ED includes a capping layer (not illustrated), the encapsulation layer TFE may be disposed on the capping layer (not illustrated). The encapsulation layer TFE may include at least one organic layer (hereinafter referred to as an organic encapsulation layer) and at least one inorganic layer (hereinafter referred to as an inorganic encapsulation layer), and the inorganic encapsulation layer and the organic encapsulation layer may be alternately disposed.

The inorganic encapsulation layer protects the display element layer DP-ED from moisture and/or oxygen, and the organic encapsulation layer protects the display element layer DP-ED from foreign substances such as dust particles. The inorganic encapsulation layer may include silicon nitride, silicon oxynitride, silicon oxide, titanium oxide, or aluminum oxide, but is not limited thereto. The organic encapsulation layer may include an acrylic-based compound, an epoxy-based compound, or the like. The organic encapsulation layer may include a photopolymerizable organic material but is not limited thereto.

Referring to FIG. 3, a display device DD according to an embodiment may include a light control layer CCL disposed on the display panel DP. The light control layer CCL may include division patterns BMP and light control parts CCP1, CCP2, and CCP3.

The light control parts CCP1, CCP2, and CCP3 may each change a wavelength of light provided from the display element layer DP-ED or may transmit the provided light without changing the wavelength of the light. The first and second light control parts CCP1 and CCP2 according to an embodiment may be formed by a coating process or an inkjet process from an ink composition according to an embodiment, which will be described later. The ink composition in a solution state may be provided between division patterns BMP spaced apart from each other, and the provided ink composition may be converted into a film that is cured through a UV exposure process and a bake process to form the first and second light control parts CCP1 and CCP2. For example, the first and second light control parts CCP1 and CCP2 may be formed from the ink composition containing a quantum dot, a first monomer which is an acrylate-based monomer, a second monomer represented by Formula 1, a scatterer, and an initiator.

When the first and second light control parts CCP1 and CCP2 are formed using an ink composition which does not include the second monomer, quantum dots may deteriorate during the UV exposure process and the bake process, and thus the photoconversion efficiency of the first and second light control parts CCP1 and CCP2 may be lowered. The ink composition according to an embodiment may include the second monomer to prevent deterioration of the quantum dots, and thus the photoconversion efficiency of the first and second light control parts CCP1 and CCP2 that are formed may be maintained at a high level, even after the UV exposure process and the bake process is performed. The ink composition according to an embodiment, from which the first and second light control parts CCP1 and CCP2 are formed, will be described in further detail below.

The light control layer CCL according to an embodiment may include quantum dots QD. The quantum dots QD may include first quantum dots QD1 and second quantum dots QD2. For example, the first light control part CCP1 may include the first quantum dots QD1 that convert the third light into the first light, the second light control part CCP2 may include the second quantum dots QD2 that convert the third light to the second light, and the third light control part CCP3 may transmit the first light. The third light may have a central wavelength in a range of about 440 nm to about 460 nm, the first light may have a central wavelength in a range of about 600 nm to about 640 nm, and the second light may have a central wavelength in a range of about 510 nm to about 540 nm.

The first light control part CCP1 may provide red light, which is the first light, the second light control part CCP2 may provide green light, which is the second light, and the third light control part CCP3 may transmit and provide blue light, which is the third light among source light provided from the light-emitting element ED. For example, the first quantum dots QD1 may be red quantum dots and the second quantum dots QD2 may be green quantum dots.

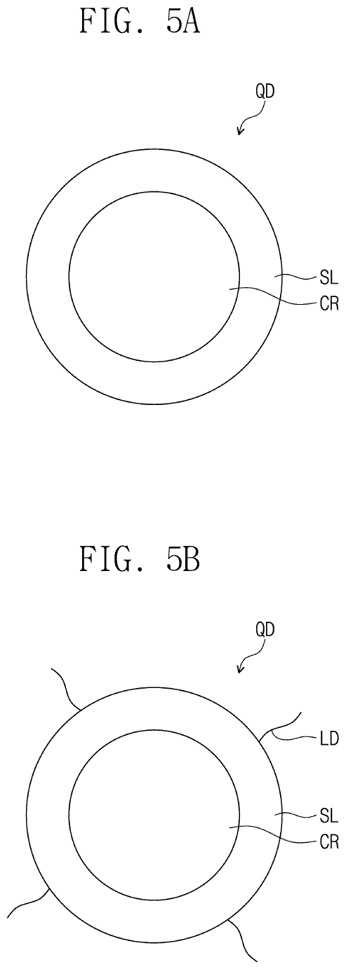

FIGS. 5A and 5B are each a schematic cross-sectional view of a structure of a quantum dot according to an embodiment.

Referring to FIG. 5A, the quantum dot QD may include a core CR and a shell SL covering the core CR. In an embodiment, the core CR may contain a Group III-V semiconductor compound. The core CR may contain an InP compound as a Group III-V semiconductor compound. The core CR may contain indium (In) and phosphorus (P). The core CR may contain a binary compound composed of indium and phosphorus. The quantum dot QD according to an embodiment includes the core CR containing a Group III-V semiconductor compound, and thus may emit light having a selected maximum light-emitting wavelength. For example, the first quantum dot QD1 may absorb blue light and emit red light, and the second quantum dot QD2 may absorb blue light and emit green light.

In an embodiment, the shell SL of the quantum dot QD may serve as a protective layer for maintaining semiconductor characteristics by preventing chemical denaturation of the core CR and/or may serve as a charging layer for imparting electrophoretic characteristics to the quantum dot QD. The shell SL may be a single layer or a multi-layer. The shell SL may contain a Group II-VI compound. For example, the shell SL may be formed of a ZnS compound.

The quantum dot QD may have a full width at half maximum (FWHM) of an emission wavelength spectrum equal to or less than about 45 nm. For example, the quantum dot QD may have a FWHM of an emission wavelength spectrum equal to or less than about 40 nm. For example, the quantum dot QD may have a FWHM of an emission wavelength spectrum equal to or less than about 30 nm. Within any of the above ranges, color purity or color reproducibility may be improved. Light emitted through the quantum dot QD may be emitted in all directions, so that a wide viewing angle may be improved.

The quantum dot QD may have any shape that is used in the related art, and is not limited thereto. For example, the quantum dot QD may have a spherical shape, a pyramidal shape, -a multi-arm-like shape, or a cubic shape, or the quantum dot QD may be in the form of a nanoparticle, a nanotube, a nanowire, a nanofiber, a nanoplate-like particle, etc.

The quantum dot QD may control the color of emitted light according to a particle size thereof, and therefore, the quantum dot QD may have various emission colors such as red light and green light. In an embodiment, the first quantum dot QD1 included in the first light control part CCP1 overlapping the first pixel region PXA-R may emit red light. As the particle size of the quantum dot QD decreases, light having a shorter wavelength may be emitted. For example, among quantum dots QD having a same core CR, a particle size of the second quantum dot QD2, which emits green light, may be smaller than a particle size of the first quantum dot QD1, which emits red light. However, embodiments are not limited thereto, and even among quantum dots QD having a same core CR, the particle size may be controlled depending on a shell forming material, a shell thickness, etc.

Referring to FIG. 5B, the quantum dot QD may further include a ligand LD chemically bonded to the surface thereof. The ligand LD may be chemically bonded to the surface of the quantum dot QD to passivate the quantum dot QD. For example, the quantum dot QD may further include a ligand LD chemically bonded to the shell SL. In an embodiment, the ligand LD may include a thiol group (—SH) or a carboxylic acid group (—COOH). For example, the ligand LD may include polyethylene glycol and may have a thiol group (—SH) or a carboxylic acid group (—COOH) as an end group.

Referring to FIG. 3 again, the light control layer CCL may include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot, and may include the scatterer SP.

The scatterer SP may be an inorganic particle. For example, the scatterer SP may include at least one of TiO₂, Al₂O₃, SiO₂, ZnO, ZrO₂, BaTiO₃, Ta₂O₅, Ti₃O₅, ITO, IZO, ATO, ZnO—Al, Nb₂O₃, SnO, and MgO. The scatterer SP may include any one of TiO₂, Al₂O₃, SiO₂, ZnO, ZrO₂, BaTiO₃, Ta₂O₅, Ti₃O₅, ITO, IZO, ATO, ZnO—Al, Nb₂O₃, SnO, and MgO, or the scatterer SP may be a mixture of two or more materials selected from TiO₂, Al₂O₃, SiO₂, ZnO, ZrO₂, BaTiO₃, Ta₂O₅, Ti₃O₅, ITO, IZO, ATO, ZnO—Al, Nb₂O₃, SnO, and MgO.

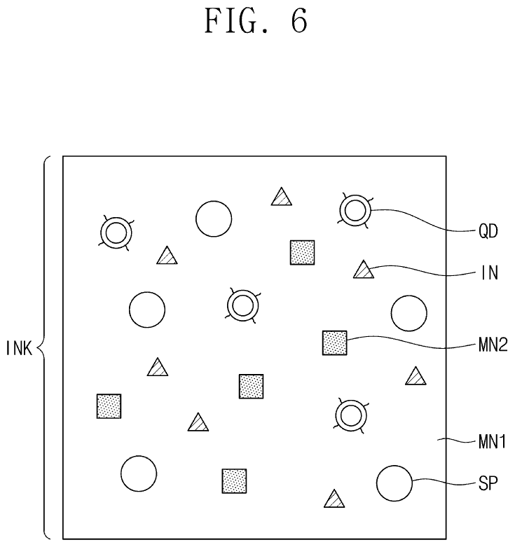

The first light control part CCP1, the second light control part CCP2, and the third light control part CCP3 may respectively include base resins BR1, BR2, and BR3 in which the quantum dots QD1 and QD2, and/or the scatterer SP may be dispersed. The base resins BR1, BR2, and BR3 may each correspond to the first monomer MN1 (see FIG. 6) included in the ink composition according to an embodiment. The first light control part CCP1 and the second light control part CCP2 may each include an antioxidant monomer MN2 (see FIG. 6) in which a phosphorus-based antioxidant, a phenol-based antioxidant, or a sulfur-based antioxidant is covalently bonded to an acrylate-based monomer. The antioxidant monomer MN2 may correspond to a second monomer MN2 (see FIG. 6) included in the ink composition according to an embodiment, which will be described later, and is denoted with the same reference or symbol as that of the second monomer MN2 (see FIG. 6).

In an embodiment, the first light control part CCP1 may include the first quantum dot QD1, the scatterer SP, and the antioxidant monomer MN2, which are dispersed in the first base resin BR1, the second light control part CCP2 may include the second quantum dot QD2, the scatterer SP, and the antioxidant monomer MN2, which are dispersed in the second base resin BR2, and the third light control part CCP3 may include the scatterer SP which is dispersed in the third base resin BR3. The base resins BR1, BR2, and BR3 are media in which the quantum dots QD1 and QD2 and the scatterer SP are dispersed, and may each be, for example, an acrylate-based monomer. In an embodiment, the first base resin BR1, the second base resin BR2, and the third base resin BR3 may be the same as or different from each other. The antioxidant monomer MN2 may prevent the deterioration of the first and second quantum dots QD1 and QD2, and the antioxidant monomers MN2 included in the first and second light control parts CCP1 and CCP2 may be the same as or different from each other.

The light control layer CCL may include a barrier layer BFL1. The barrier layer BFL1 may prevent penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may also be provided between the light control parts CCP1, CCP2, and CCP3 and the filters CF1, CF2, and CF3.

The barrier layers BFL1 and BFL2 may each include at least one inorganic layer. For example, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a thin metal film having secured light transmittance, or the like. The barrier layers BFL1 and BFL2 may each further include an organic film. The barrier layers BFL1 and BFL2 may each be formed of a single layer or of multiple layers.

In a display device DD according to an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light blocking part BM and filters CF1, CF2, and CF3. The color filter layer CFL may include a first filter CF1, which transmits the first light, a second filter CF2, which transmits the second light, and a third filter CF3, which transmits the third light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymer photosensitive resin and may include no pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may be integrally provided without being distinguished from each other.

The light blocking part BM may be a black matrix. The light blocking part BM may include an organic or inorganic light blocking material containing a black pigment or a black dye. The light blocking part BM may prevent light leakage and may define boundaries between adjacent filters CF1, CF2, and CF3. In an embodiment, the light blocking part BM may be formed of a blue filter.

The first to third filters CF1, CF2, and CF3 may be disposed to respectively correspond to the first pixel region PXA-R, which emits red light, the second pixel region PXA-G, which emits green light, and the third pixel region PXA-B, which emits blue light. The first to third filters CF1, CF2, and CF3 may be disposed to respectively correspond to the first to third light control parts CCP1, CCP2, and CCP3. For example, on a cross-section parallel to the thickness direction, a minimum width of each of the first to third light control parts CCP1, CCP2, and CCP3 may be substantially the same as a minimum width of each of the first to third filters CF1, CF2, and CF3.

Although not shown in the drawings, the filters CF1, CF2, and CF3, which transmit different light, may be disposed to overlap at least a portion of the peripheral regions NPXA, which are disposed between the pixel regions PXA-R, PXA-B, and PXA-G. For example, the filters CF1, CF2, and CF3 may be disposed to overlap each other in the third direction DR3, which is the thickness direction, and may thus define boundaries between adjacent pixel regions PXA-R, PXA-B, and PXA-G.

A display device DD according to an embodiment may further include a base layer BL disposed on the color filter layer CFL. The base layer BL may provide a base surface on which the color filter layer CFL, the light control layer CCL, and the like are disposed. The base layer BL may be a glass substrate, a metal substrate, a plastic substrate, etc. However, embodiments are not limited thereto, and the base layer BL may include an inorganic layer, an organic layer, or a composite material layer. Although not shown in the drawings, in an embodiment, the base layer BL may be omitted.

Hereinafter, an ink composition according to an embodiment will be described in detail with reference to FIG. 6. FIG. 6 is a schematic cross-sectional view of an ink composition according to an embodiment.

The ink composition INK according to an embodiment may be a material from which the first and second light control parts CCP1 and CCP2 (see FIG. 3) of the light control layer CCL (see FIG. 3) are formed. The ink composition INK according to an embodiment may include a quantum dot QD, a first monomer MN1, a second monomer MN2, a scatterer SP, and an initiator IN.

The quantum dot QD included in the ink composition INK according to an embodiment may include a core CR (see FIG. 5A) and a shell SL (see FIG. 5A) covering the core CR (see FIG. 5A), and may further include a ligand LD (see FIG. 5B) bonded to the surface of the quantum dot QD. The quantum dot QD included in the ink composition INK may be the same as the quantum dot QD that has been described above with reference to FIGS. 5A and 5B. In an embodiment, the quantum dot QD may be provided in the ink composition INK while being dispersed in an organic solvent. The ligand LD (see FIG. 5B) bonded to the surface of the quantum dot QD may increase the dispersibility of the quantum dot QD in the organic solvent. Examples of an organic solvent may include hexane, toluene, chloroform, dimethyl sulfoxide, dimethyl formamide, or the like. However, embodiments are not limited thereto.

In an embodiment, if the organic solvent is selected, a quantum dot dispersion may be prepared by dispersing the quantum dot QD in the organic solvent, and an ink composition INK may be prepared by mixing the quantum dot dispersion with the first monomer MN1, the second monomer MN2, the scatterer SP, and the initiator IN. In an embodiment, an amount of the quantum dot QD that is included in the ink composition INK may be in a range of about 30 wt % to about 50 wt %, with respect to a total weight of the ink composition INK. When the amount of the quantum dot QD included in the ink composition INK is below about 30 wt %, light efficiency may be lowered. When the amount of the quantum dot QD is above about 50 wt %, the viscosity of the ink composition INK increases, thus making it difficult to apply the quantum dot QD by an inkjet process. When the amount of the quantum dot QD included in the ink composition INK satisfies the above-mentioned amount range, the first light control part CCP1 (see FIG. 3) and the second light control part CCP2 (see FIG. 3), which are formed of the ink composition INK, may exhibit desired color reproducibility and light extraction efficiency.

The ink composition INK according to an embodiment may include the first monomer MN1. The first monomer MN1 may be a medium in which the quantum dots QD1 and QD2, and the scatterer SP are dispersed. For example, the first monomer MN1 may include an acrylate-based monomer. For example, the acrylate-based monomer may be 1,6-hexanediol diacrylate, but is not limited thereto. In an embodiment, an amount of the first monomer MN1 that is included in the ink composition INK may be in a range of about 45 wt % to about 55 wt %, with respect to a total weight of the ink composition INK. When the amount of the first monomer MN1 in the ink composition INK falls within the above-mentioned range, each component included in the ink composition INK is excellent in solubility, and thus the single-film characteristics of the first light control part CCP1 (see FIG. 3) and the second light control part CCP2 (see FIG. 3) may be excellent.

The ink composition INK according to an embodiment may include the second monomer MN2. The second monomer MN2 may include a structure in which a phosphorus-based antioxidant, a phenol-based antioxidant, or a sulfur-based antioxidant is chemically bonded (for example, covalently bonded) to the acrylate-based monomer, and may be represented by Formula 1 or Formula 1-A:

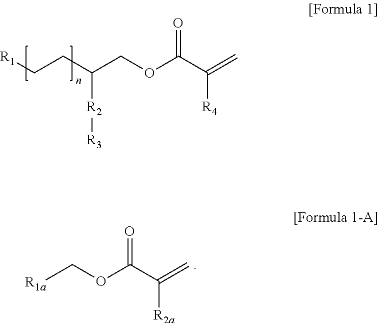

In Formula 1, R₁ may be an acrylate group or a group represented by one of Formulas 2 to 4. In Formula 1, R₂ may be a direct linkage or a substituted or unsubstituted divalent oxy group. For example, when R₁ is an acrylate group, R₂ may be a direct linkage or a substituted or unsubstituted divalent alkyloxy group having 1 to 10 carbon atoms. As another example, when R₁ is a group represented by one of Formulas 2 to 4, R₂ may be a direct linkage.

In Formula 1, R₃ may be a hydrogen atom or a group represented by one of Formulas 2 to 4. However, R₃ and R₁ may not each be a group represented by one of Formulas 2 to 4 at a same time. For example, in Formula 1, one of R₁ and R₃ may be a group represented by one of Formulas 2 to 4.

In Formula 1, R₄ may be a hydrogen atom or a methyl group. For example, the second monomer MN2 represented by Formula 1 may include at least one acrylate group or methacrylate group. In the specification, the term “acrylate” may have a same meaning as (meth)acrylate and (metha)acrylate. In the specification, the term “methyl acrylate” may have a same meaning as methyl (meth)acrylate and methyl(metha)acrylate.

In Formula 1, n may be an integer from 0 to 10. For example, n may be 0 or 1. For example, the second monomer MN2 represented by Formula 1 may not include an ethylene group, or may not include one ethylene group.

In Formula 1-A, R₁ₐ may be a group represented by one of Formulas 2 to 4, and R₂ₐ may be a hydrogen atom or a methyl group.

The second monomer MN2 represented by Formula 1 may correspond to the above-described acrylate-based monomer, and Formulas 2 to 4 may respectively correspond to a phosphorus-based antioxidant, a phenol-based antioxidant, and a sulfur-based antioxidant.

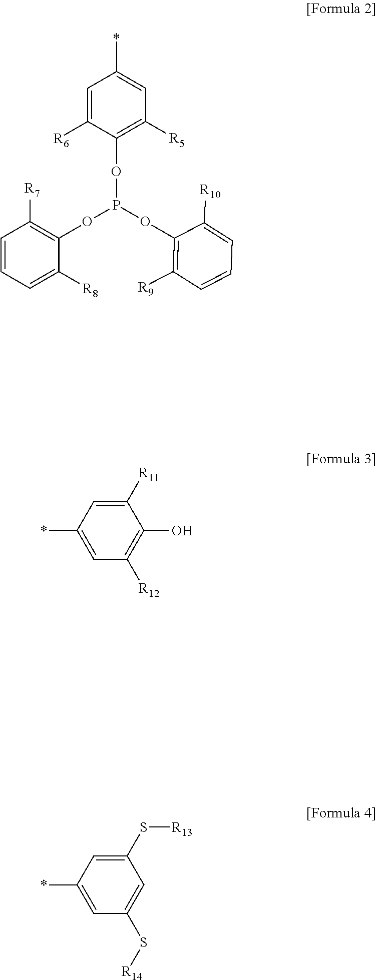

In Formulas 2 and 3, R₅ to R₁₂ may each independently be a substituted or unsubstituted alkyl group having 1 to 10 carbon atoms. For example, R₅ to R₁₀ may each independently be a substituted or unsubstituted t-butyl group. For example, R₁₁ and R₁₂ may each independently be a substituted or unsubstituted methyl group or a substituted or unsubstituted t-butyl group. However, embodiments are not limited thereto. In Formula 4, R₁₃ and R₁₄ may each independently be a substituted or unsubstituted alkyl group having 1 to 10 carbon atoms or a substituted or unsubstituted aryl group having 3 to 10 ring-forming carbon atoms. For example, R₁₃ and R₁₄ may each independently be a substituted or unsubstituted a n-butyl group. However, embodiments are not limited thereto. In Formulas 2 to 4, *-represents a bonding site to a neighboring atom.

In an embodiment, the second monomer MN2 represented by Formula 1 may be represented by Formula 1-1 or Formula 1-2. In Formulas 1-1 and 1-2, R₄ and n are each the same as defined in Formula 1.

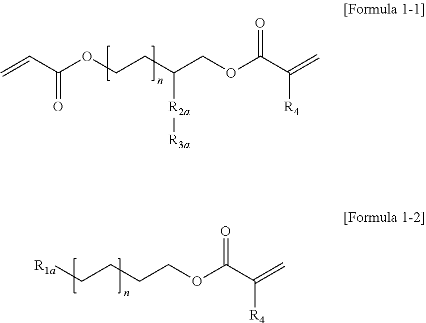

In Formula 1-1, R₂ₐ may be a direct linkage or a substituted or unsubstituted divalent alkyloxy group having 1 to 10 carbon atoms. For example, R₂ₐ may be a direct linkage or a substituted or unsubstituted divalent methoxy group. In Formula 1-1, R₃ₐ may be a group represented by one of Formulas 2 to 4.

In an embodiment, the second monomer MN2 represented by Formula 1-1 may include two group that are selected from an acrylate group and a methacrylate group. For example, the second monomer MN2 according to an embodiment, represented by Formula 1-1, may include two acrylate groups, or include one acrylate group and one methacrylate group.

In Formula 1-2, R₁ₐ may be a group represented by one of Formulas 2 to 4. In an embodiment, the second monomer MN2 represented by Formula 1-2 may include one group selected from an acrylate group or a methacrylate group. For example, the second monomer MN2 represented by Formula 1-2 may include an acrylate group or a methacrylate group.

In an embodiment, a second monomer MN2 represented by Formula 1 or Formula 1-A may include at least one compound selected from Compound Group 1.

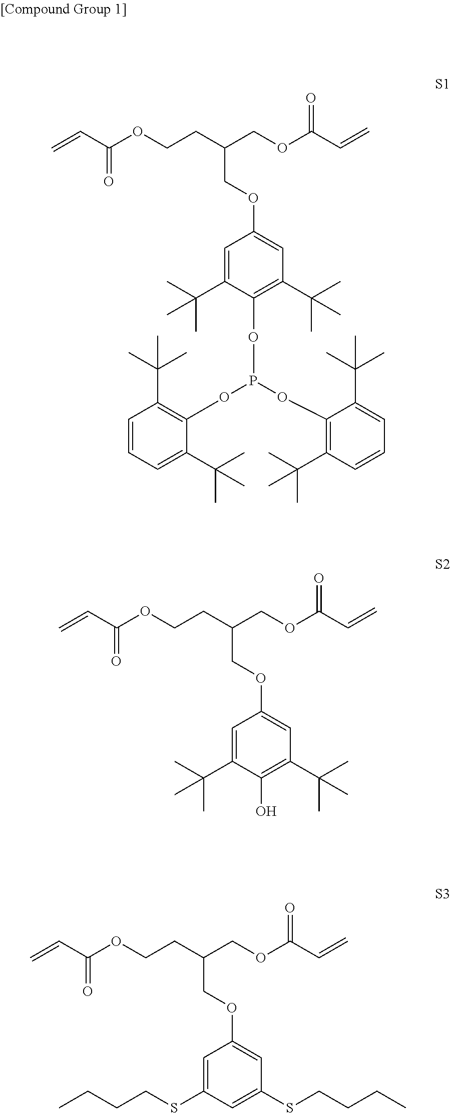

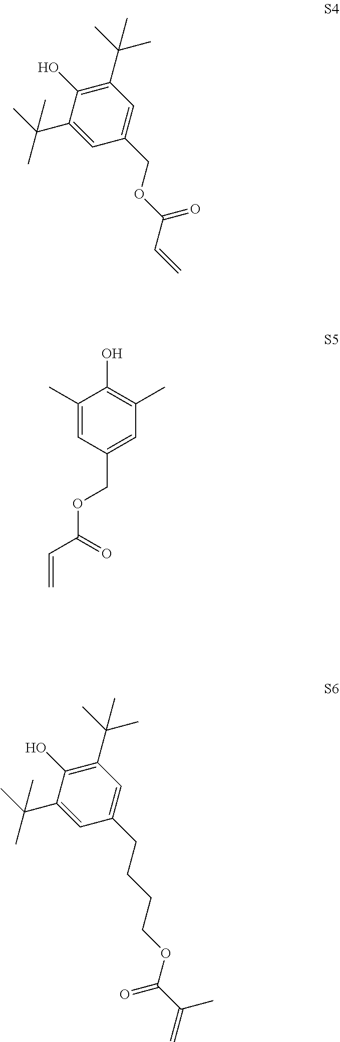

In the second monomer MN2, a phosphorus-based antioxidant represented by Formula 2, a phenol-based antioxidant represented by Formula 3, or a sulfur-based antioxidant represented by Formula 4 may be bonded to an acrylate-based monomer represented by Formula 1, and thus the second monomer MN2 according to an embodiment may have excellent chemical stability and excellent solubility in the ink composition INK. Accordingly, the second monomer MN2 may be included in the ink composition INK in an excessive amount compared to an antioxidant, which is not chemically bonded to the acrylate-based monomer, and thus the first and second light control parts CCP1 and CCP2 (see FIG. 3) formed from the ink composition INK through an UV exposure process and a bake process may maintain a high photoconversion efficiency. Since the ink composition INK, which includes the second monomer MN2, does not substantially generate any out-gas, it is possible to prevent cracks occurring in a single film (for example, the first and second light control parts CCP1 and CCP2) itself during any subsequent process steps.

According to an embodiment, an amount of the second monomer MN2 included in the ink composition INK may be in a range of about 1 wt % to about 20 wt %, with respect to a total weight of the ink composition. In an embodiment, an amount of the second monomer MN2 may be in a range of about 1 wt % to about 10 wt %, with respect to a total weight of the ink composition. For example, an amount of the second monomer MN2 may be about 1 wt %, about 5 wt %, or about 10 wt %, with respect to a total weight of the ink composition. When the amount of the second monomer MN2 in the ink composition INK falls within any of the above-mentioned ranges, a single film formed after performing the UV exposure process and the bake process has a good surface condition, thereby improving a photoconversion efficiency maintenance rate between film formation processes. In an embodiment, when the amount of the second monomer MN2 falls within any of the above-mentioned ranges, the amount of out-gas occurring during the high-temperature bake process at about 180° C. to about 220° C. is lowered, and thus defects due to the out-gas in any subsequent process steps may be reduced.

In an embodiment, the description of the scatterer SP, which has been made with reference to FIG. 3, may be applied to the scatterer SP included in the ink composition INK. For example, the scatterer SP may be TiO₂. According to an embodiment, an amount of the scatterer SP included in the ink composition INK may be in a range of about 1 wt % to about 10 wt %, with respect to a total weight of the ink composition INK. For example, the scatterer SP may be included in an amount of about 4 wt %, with respect to a total weight of the ink composition INK, but embodiments are not limited thereto. When the amount of the scatterer SP included in the ink composition INK according to an embodiment falls within the above-mentioned range, a path of light spontaneously emitted from the quantum dot QD through the scatterer SP is increased, thereby improving the light efficiency of the first and second light control parts CCP1 and CCP2.

In an embodiment, the initiator IN is a compound for initiating polymerization of the first monomer MN1 and any radical initiator may be used as an initiator without particular limitation. For example, the initiator IN may be 2,4,6-trimethylbenzoyl-diphenyl phosphine oxide (TPO).

According to an embodiment, an amount of the initiator IN included in the ink composition INK may be in a range of about 1 wt % to about 3 wt %, with respect to a total weight of the ink composition INK. For example, the initiator IN may be included at an amount of about 1 wt %, but is not limited thereto.

Hereinafter, an ink composition according to an embodiment will be explained with reference to the Examples and the Comparative Examples. The Examples described below are only provided as illustrations to assist in understanding the disclosure, and the scope thereof is not limited thereto.

### EXAMPLES AND COMPARATIVE EXAMPLES

### 1) Preparation of Ink Compositions According to Example Groups A to F, and Comparative Example Groups A and B

Ink compositions of Example Groups A to F, and Comparative Example Groups A and B according to ingredients and contents listed in Table 1 below were prepared by controlling content ratio of the second monomer or antioxidant (content unit:wt %).

TABLE 1

| | | Comparative | Comparative | | | | | | |
|---|---|---|---|---|---|---|---|---|---|
| | | Example | Example | Example | Example | Example | Example | Example | Example |
| | | group A | group B | group A | group B | group C | group D | group E | group F |
| Quantum | QD-1 | 40 | 40 | 40 | 40 | 40 | 40 | 40 | 40 |
| dot | QD-2 | — | — | — | — | — | — | — | |
| | QD-3 | — | — | — | — | — | — | — | |
| First | HDDA | 55 | 54.5/54/50/ | 54/50/45/ | 54/50/45/ | 54/50/45/ | 54/50/45/ | 54/50/45/ | 54/50/45/ |
| monomer | | | 45/35/15 | 35/15 | 35/15 | 35/15 | 35/15 | 35/15 | 35/15 |
| Second | Compound S1 | — | — | 1/5/10/ | — | — | — | — | — |
| monomer | | | | 20/40 | | | | | |
| | Compound S2 | — | — | — | 1/5/10/ | — | — | — | — |
| | | | | | 20/40 | | | | |
| | Compound S3 | — | — | — | — | 1/5/10/ | — | — | — |
| | | | | | | 20/40 | | | |
| | Compound S4 | — | — | — | — | — | 1/5/10/ | — | — |
| | | | | | | | 20/40 | | |
| | Compound S5 | — | — | — | — | — | — | 1/5/10/ | — |
| | | | | | | | | 20/40 | |
| | Compound S6 | — | — | — | — | — | — | — | 1/5/10/ |
| | | | | | | | | | 20/40 |
| Antioxidant | | — | 0.5/1/5/10/ | — | — | — | — | — | — |
| | | | 20/40 | | | | | | |
| Scatterer | TiO₂ | 4 | 4 | 4 | 4 | 4 | 4 | 4 | 4 |
| Initiator | TPO | 1 | 1 | 1 | 1 | 1 | 1 | 1 | 1 |

1) Example group A: Examples A-1 to A-5
2) Example group B: Examples B-1 to B-5
3) Example group C: Examples C-1 to C-5
4) Example group D: Examples D-1 to D-5
5) Example group E: Examples E-1 to E-5
6) Example group F: Examples F-1 to F-5
7) Comparative Example group A: Comparative Example A-1
8) Comparative Example group B: Comparative Examples B-1 to B-6
Examples A-1, B-1, C-1, D-1, E-1, and F-1, and Comparative Example B-2: first monomer content of about 54 wt %, the second monomer (or antioxidant) content of about 1 wt %
Examples A-2, B-2, C-2, D-2, E-2, and F-2, and Comparative Example B-3: first monomer content of about 50 wt %, the second monomer (or antioxidant) content of about 5 wt %
Examples A-3, B-3, C-3, D-3, E-3, and F-3, and Comparative Example B-4: first monomer content of about 45 wt %, the second monomer (or antioxidant) content of about 10 wt %
Examples A-4, B-4, C-4, D-4, E-4, and F-4, and Comparative Example B-5: first monomer content of about 35 wt %, the second monomer (or antioxidant) content of about 20 wt %
Examples A-5, B-5, C-5, D-5, E-5, and F-5, and Comparative Example B-6: first monomer content of about 15 wt %, the second monomer (or antioxidant) content of about 40 wt %
Comparative Example A-1: the first monomer content of about 55 wt %
Comparative Example B-1: the first monomer content of about 54.5 wt %, antioxidant of about 0.5 wt %
<Material>
QD-1: mPEG4-CH₃COOH is used as a ligand on surface of quantum dot including InP core and ZnS shell
QD-2: mPEG4-CH₃COOH and mPEG5-SH are used, as a ligand, by mixing at molar ratio of mPEG4-CH₃COOH:mPEG5-SH = 2:1 on the surface of quantum dot including InP core and ZnS shell
QD-3: mPEG4-CH₃COOH and mPEG5-SH are used, as a ligand, by mixing at molar ratio of mPEG4-CH₃COOH:mPEG5-SH = 2:1 on surface of quantum dot including InP core and ZnS shell
HDDA: 1,6-hexanediol diacrylate
Compounds S1 to S6: compounds S1 to S6 in Compound Group 1
TPO: 2,4,6-trimethylbenzoyl-diphenyl phosphine oxide antioxidant: [2,2-bis[(2,6-ditert-butyl-4-methylphenoxy)methyl]-3-dihydroxyphosphanyloxypropyl] dihydrogen phosphite

### 2) Evaluation of Photoconversion Efficiency Maintenance Rate

Photoconversion efficiency maintenance rates of each Example Groups and Comparative Example Groups are listed in Table 2. In Table 2, the photoconversion efficiency maintenance rate is a photoconversion efficiency maintenance rate during the film formation processes, and is shown as an average value by measuring photoconversion efficiencies after coating the ink composition onto a substrate, and during the exposure process and the high-temperature bake process.

For example, the ink composition of each Example Group or Comparative Example Group was applied onto a substrate at a thickness of about 10 μm using a spin coater. Exposure (exposure amount: about 12 J) with an exposer, which emits light in a wavelength of about 395 nm was performed, and the bake process was performed at about 180° C. for about 30 minutes in a nitrogen (N₂) atmosphere to prepare a film (a single film). During this exposure process and bake process, the photoconversion efficiency was measured, and an average value thereof was listed in Table 2.

TABLE 2

| | Content of antioxidant or second monomer | | | | | | |
|---|---|---|---|---|---|---|---|
| | 0 wt % | 0.5 wt % | 1 wt % | 5 wt % | 10 wt % | 20 wt % | 40 wt % |
| Comparative | 83.50% | — | — | — | — | — | — |
| Example group A | | | | | | | |
| Comparative | — | 88.30% | Poor membrane condition | | | | |
| Example group B | | | | | | | |
| Example group A | — | — | 88.20% | 93.60% | 95.10% | 94.90% | 80.10% |
| Example group B | — | — | 85.40% | 89.20% | 93.00% | 93.40% | 80.20% |
| Example group C | — | — | 89.10% | 95.30% | 97.20% | 96.50% | 81.50% |
| Example group D | — | — | 86.10% | 87.90% | 92.40% | 93.00% | 79.10% |
| Example group E | — | — | 85.70% | 90.10% | 90.20% | 90.10% | 81.10% |
| Example group F | — | — | 86.00% | 88.50% | 91.10% | 91.30% | 78.30% |

1) Example group A: average value of photoconversion efficiencies of Examples A-1 to A-5
2) Example group B: average value of photoconversion efficiencies of Examples B-1 to B-5
3) Example group C: average value of photoconversion efficiencies of Examples C-1 to C-5
4) Example group D: average value of photoconversion efficiencies of Examples D-1 to D-5
5) Example group E: average value of photoconversion efficiencies of Examples E-1 to E-5
6) Example group F: average value of photoconversion efficiencies of Examples F-1 to F-5
7) Comparative Example group A: photoconversion efficiencies of Comparative Example A-1
8) Comparative Example group B: average value of photoconversion efficiencies of Comparative Examples B-1 to B-6

Referring to Table 2, it was confirmed that Example Groups A to F, which contain the quantum dot QD-1 and use the second monomer according to embodiments had excellent chemical stability, even though the second monomer was included in an excessive amount, thereby exhibiting a good level of photoconversion efficiency maintenance rate. It can be confirmed that, when the second monomer of Example Groups A to F is included in an amount range of about 1 wt % to about 20 wt %, the photoconversion efficiency maintenance rate is excellent even after film formation processes (exposure, bake) are performed.

In comparison, Comparative Example Group A, which contains no second monomer according to an embodiment, exhibited the photoconversion efficiency maintenance rate of about 83.50%. Comparative Example Group B, in which an antioxidant different from the second monomer according to an embodiment was used in a small amount of about 0.5 wt %, exhibited an improved photoconversion efficiency maintenance rate compared to Comparative Example Group A. However, it was confirmed that when the antioxidant was used in an amount equal to or greater than about 1 wt %, the solubility of the antioxidant becomes poorer, resulting in non-uniform single-film conditions, such as cracks occurring in the single film.

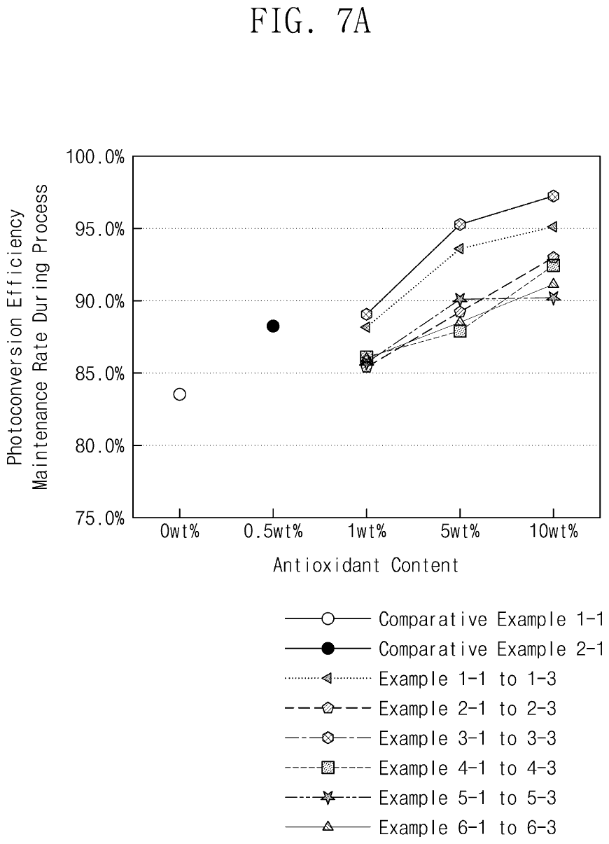

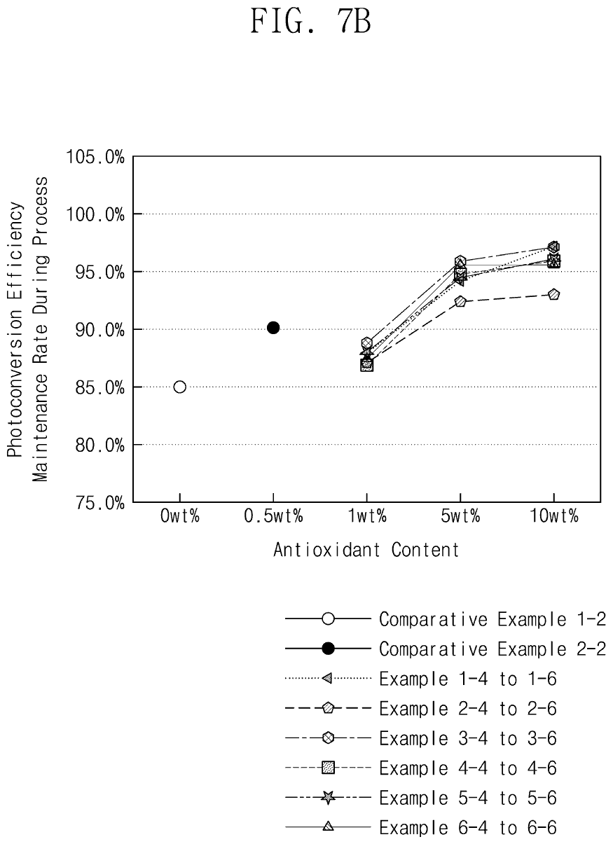

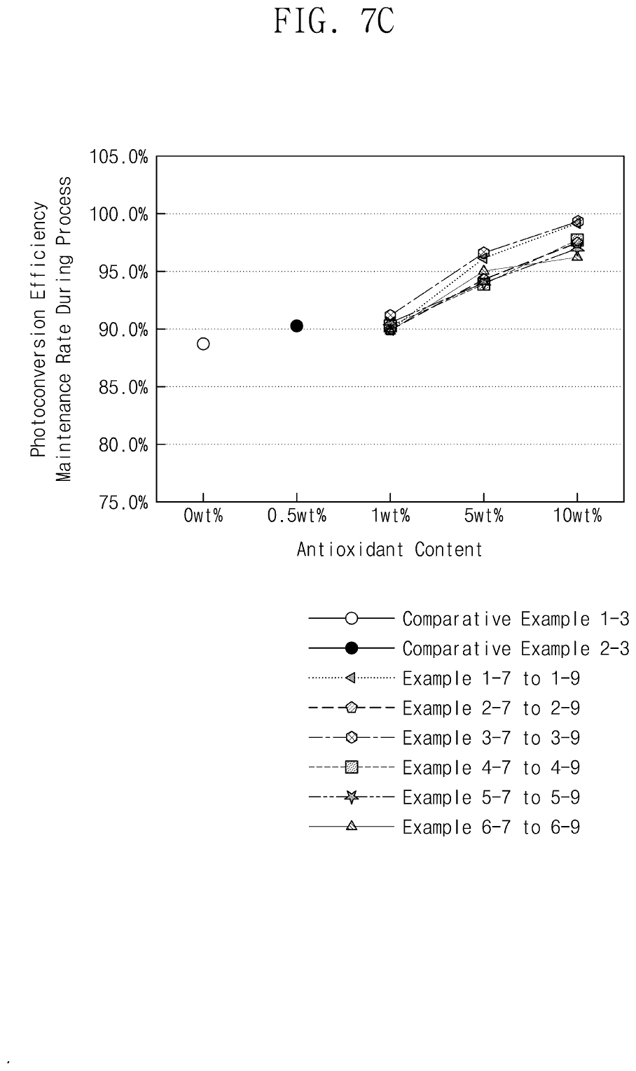

Ink compositions according to the Examples among Example Groups A to F, which include the second monomer in an amount of about 1 wt %, about 5 wt %, and about 10 wt % and have high photoconversion efficiency maintenance rate during processes, were respectively sub-classified into Examples 1-1 to 1-3, Examples 2-1 to 2-3, Examples 3-1 to 3-3, Examples 4-1 to 4-3, Examples 5-1 to 5-3, and Examples 6-1 to 6-3, and the photoconversion efficiency maintenance rates of these sub-classified Examples were measured. The measurement results are shown in FIG. 7A. In FIG. 7A, the antioxidant content in each of Examples 1-1 to 1-3, Examples 2-1 to 2-3, Examples 3-1 to 3-3, and Examples 4-1 to 4-3, Examples 5-1 to 5-3, and Examples 6-1 to 6-3 on the x-axis indicates the content of the second monomer.

Examples 1-1 to 1-3 were selected from Example Group A. The second monomer was included in an amount of about 1 wt % in Example 1-1. The second monomer was included in an amount of about 5 wt % in Example 1-2. The second monomer was included in an amount of about 10 wt % in Example 1-3.

Examples 2-1 to 2-3 were selected from Example Group B. The second monomer was included in an amount of about 1 wt % in Example 2-1. The second monomer was included in an amount of about 5 wt % in Example 2-2. The second monomer was included in an amount of about 10 wt % in Example 2-3.

Examples 3-1 to 3-3 were selected from Example Group C. The second monomer was included in an amount of about 1 wt % in Example 3-1. The second monomer was included in an amount of about 5 wt % in Example 3-2. The second monomer was included in an amount of about 10 wt % in Example 3-3.

Examples 4-1 to 4-3 were selected from Example Group D. The second monomer was included in an amount of about 1 wt % in Example 4-1. The second monomer was included in an amount of about 5 wt % in Example 4-2. The second monomer was included in an amount of about 10 wt % in Example 4-3.

Examples 5-1 to 5-3 were selected from Example Group E. The second monomer was included in an amount of about 1 wt % in Example 5-1. The second monomer was included in an amount of about 5 wt % in Example 5-2. The second monomer was included in an amount of about 10 wt % in Example 5-3.

Examples 6-1 to 6-3 were selected from Example Group F. The second monomer was included in an amount of about 1 wt % in Example 6-1. The second monomer was included in an amount of about 5 wt % in Example 6-2. The second monomer was included in an amount of about 10 wt % in Example 6-3.

In FIG. 7A, Comparative Example 1-1 corresponds to the Comparative Example Group A, and Comparative Example 2-1 corresponds to the Comparative Example Group B.

Referring to Table 2 and FIG. 7A, it can be seen that Examples 1-1 to 1-3, 2-1 to 2-3, 3-1 to 3-3, 4-1 to 4-3, 5-1 to 5-3, and 6-1 to 6-3 each have a higher photoconversion efficiency maintenance rate during the film formation processes than Comparative Example 1-1.

On the other hand, Comparative Example 2-1 includes a small amount of an antioxidant and thus exhibited a higher photoconversion efficiency maintenance rate than some of the Examples. However, as described above, it is confirmed that, when the amount of the antioxidant included in Comparative Example 2-1 is excessively as high as the amount of the second monomer of Examples, the solubility of the antioxidant becomes poorer resulting in non-uniform single-film conditions, such as cracks occurring in the single film,

### 3) Preparation of Ink Compositions According to Example Groups G to L, and Comparative Example Groups C and D

Ink compositions of Example Groups G to L, and Comparative Example Groups C and D according to ingredients and contents listed in Table 3 were prepared by controlling the content ratio of the second monomer or the antioxidant, and the photoconversion efficiency maintenance rates of Example Groups and Comparative Example Groups were listed in Table 4. (content unit:wt %). The photoconversion efficiency maintenance rates of Example Groups G to L, Comparative Example Groups C and D were measured in the same manner as those of Example Groups A to F, and Comparative Example Groups A and B.

TABLE 3

| | | Comparative | Comparative | | | | | | |
|---|---|---|---|---|---|---|---|---|---|
| | | Example | Example | Example | Example | Example | Example | Example | Example |
| | | group C | group D | group G | group H | group I | group J | group K | group L |
| Quantum | QD-1 | — | — | — | — | — | — | — | — |
| dot | QD-2 | 40 | 40 | 40 | 40 | 40 | 40 | 40 | 40 |
| | QD-3 | — | — | — | — | — | — | — | — |
| First | HDDA | 55 | 54.5/54/50/ | 54/50/45/ | 54/50/45/ | 54/50/45/ | 54/50/45/ | 54/50/45/ | 54/50/45/ |
| monomer | | | 45/35/15 | 35/15 | 35/15 | 35/15 | 35/15 | 35/15 | 35/15 |
| Second | Compound S1 | — | — | 1/5/10/ | — | — | — | — | — |
| monomer | | | | 20/40 | | | | | |
| | Compound S2 | — | — | — | 1/5/10/ | — | — | — | — |
| | | | | | 20/40 | | | | |
| | Compound S3 | — | — | — | — | 1/5/10/ | — | — | — |
| | | | | | | 20/40 | | | |
| | Compound S4 | — | — | — | — | — | 1/5/10/ | — | — |
| | | | | | | | 20/40 | | |
| | Compound S5 | — | — | — | — | — | | 1/5/10/20/ | — |
| | | | | | | | | 40 | |
| | Compound S6 | — | — | — | — | — | — | — | 1/5/10/ |
| | | | | | | | | | 20/40 |
| Antioxidant | | — | 0.5/1/5/10/ | — | — | — | — | — | — |
| | | | 20/40 | | | | | | |
| Scatterer | TiO₂ | 4 | 4 | 4 | 4 | 4 | 4 | 4 | 4 |
| Initiator | TPO | 1 | 1 | 1 | 1 | 1 | 1 | 1 | 1 |

1) Example group G: Examples G-1 to G-5
2) Example group H: Examples H-1 to H-5
3) Example group I: Examples I-1 to I-5
4) Example group J: Examples J-1 to J-5
5) Example group K: Examples K-1 to K-5
6) Example group L: Examples L-1 to L-5
7) Comparative Example group C: Comparative Example C-1
8) Comparative Example group D: Comparative Examples D-1 to D-6
Examples G-1, H-1, I-1, J-1, K-1, and L-1, and Comparative Example D-2: first monomer content of about 54 wt %, second monomer (or antioxidant) content of about 1 wt %
Examples G-2, H-2, I-2, J-2, K-2, and L-2, and Comparative example D-3: first monomer content of about 50 wt %, second monomer (or antioxidant) content of about 5 wt %
Examples G-3, H-3, I-3, J-3, K-3, and L-3, and Comparative Example D-4: first monomer content of about 45 wt %, second monomer (or antioxidant) content of about 10 wt %
Examples G-4, H-4, I-4, J-4, K-4, and L-4, and Comparative Example D-5: first monomer content of about 35 wt %, second monomer (or antioxidant) content of about 20 wt %
Examples G-5, H-5, I-5, J-5, K-5, and Example L-5, and Comparative Example D-6: first monomer content of about 15 wt %, second monomer (or antioxidant) content of about 40 wt %
Comparative Example C-1: the first monomer content of about 55 wt %
Comparative Example D-1: first monomer content of about 54.5 wt %, antioxidant of about 0.5 wt %
<Material>
QD-1: mPEG4-CH₃COOH is used as a ligand on a surface of quantum dot including InP core and ZnS shell
QD-2: mPEG4-CH₃COOH: mPEG5-SH are used as a ligand by mixing at molar ratio of mPEG4-
CH₃COOH:mPEG5-SH = 2:1 on a surface of quantum dot including InP core and ZnS shell
QD-3: mPEG4-CH₃COOH:mPEGS-SH are used as a ligand by mixing at molar ratio of mPEG4-
CH₃COOH:mPEG5-SH = 1:1 on a surface of quantum dot including InP core and ZnS shell
HDDA: 1,6-hexanediol diacrylate
Compounds S1 to S6: compounds S1 to S6 in Compound Group 1
TPO: 2,4,6-Trimethylbenzoyl-diphenyl phosphine oxide
antioxidant: [2,2-bis[(2,6-ditert-butyl-4-methylphenoxy)methyl]-3-dihydroxyphosphanyloxypropyl] dihydrogen phosphite

TABLE 4

| | Content of antioxidant or second monomer | | | | | | |
|---|---|---|---|---|---|---|---|
| | 0 wt % | 0.5 wt % | 1 wt % | 5 wt % | 10 wt % | 20 wt % | 40 wt % |
| Comparative | 85.00% | ₃ | ₃ | ₃ | ₃ | ₃ | ₃ |
| Example Group C | | | | | | | |
| Comparative | | 90.10% | Poor membrane condition | | | | |
| Example Group D | | | | | | | |
| Example Group G | ₃ | ₃ | 87.90% | 94.10% | 97.20% | 98.50% | 83.50% |
| Example Group H | ₃ | ₃ | 87.10% | 92.30% | 93.00% | 92.60% | 82.10% |
| Example Group I | ₃ | ₃ | 88.80% | 95.90% | 97.10% | 97.50% | 83.10% |
| Example Group J | ₃ | ₃ | 86.90% | 95.00% | 95.80% | 96.80% | 81.90% |
| Example Group K | ₃ | ₃ | 87.70% | 94.50% | 96.10% | 95.60% | 80.50% |
| Example Group L | ₃ | ₃ | 87.50% | 95.60% | 95.60% | 94.90% | 80.10% |

1) Example Group G: average value of photoconversion efficiencies of Examples G-1 to G-5
2) Example Group H: average value of photoconversion efficiencies of Examples H-1 to H-5
3) Example Group I: average value of photoconversion efficiencies of Examples I-1 to I-5
4) Example Group J: average value of photoconversion efficiencies of Examples J-1 to J-5
5) Example Group K: average value of photoconversion efficiencies of Examples K-1 to K-5
6) Example Group L: average value of photoconversion efficiencies of Examples L-1 to L-5
7) Comparative Example Group C: photoconversion efficiencies of Comparative Example C-1
8) Comparative Example Group D: average value of photoconversion efficiencies of Comparative Examples D-1 to D-6

Referring to Table 4, Example Groups G to L, which contain the quantum dot QD-2 and use the second monomer according to an embodiment had excellent chemical stability, even though the second monomers were included in an excessive amount, thereby exhibiting a good level of the photoconversion efficiency maintenance rate. When the second monomer is included in an amount in a range of about 1 wt % to about 20 wt % in Example Groups G to L, it can be confirmed that the photoconversion efficiency maintenance rate is higher than those of Comparative Example Group C even after the film formation processes (exposure, bake) are performed.

On the other hand, Comparative Example Group C, which contains no second monomer according to an embodiment, exhibited a photoconversion efficiency maintenance rate of about 85.00%. Comparative Example Group D, which uses an antioxidant different from the second monomer according to an embodiment in a small amount of about 0.5 wt %, exhibited a higher photoconversion efficiency maintenance rate than those of Comparative Example Group C. However, it was confirmed that when containing the antioxidant in an amount equal to or greater than about 1 wt %, the solubility of the antioxidant becomes poorer resulting in non-uniform single-film condition, such as cracks occurring in the single film.

On the other hand, among Example Groups G to L, the ink compositions, which include the second monomer in an amount of about 1 wt %, about 5 wt %, and about 10 wt %, and have high photoconversion efficiency maintenance rates during processes, were respectively sub-classified into Examples 1-4 to 1-6, 2-4 to 2-6, 3-4 to 3-6, 4-4 to 4-6, 5-4 to 5-6, and 6-4 to 6-6, and the photoconversion efficiency maintenance rates of these sub-classified Examples during processes were measured. The measurement results are shown in a graph in FIG. 7B. In FIG. 7B, the antioxidant content in each of Examples 1-4 to 1-6, 2-4 to 2-6, 3-4 to 3-6, 4-4 to 4-6, 5-4 to 5-6, and 6-4 to 6-6 on the x-axis indicates the content of the second monomers.

Examples 1-4 to 1-6 were selected from the Example Group G. A second monomer is included in an amount of about 1 wt % in Example 1-4. A second monomer is included in an amount of about 5 wt % in Example 1-5. A second monomer is included in an amount of about 10 wt % in Example 1-6.

Examples 2-4 to 2-6 were selected from the Example Group H. A second monomer is included in an amount of about 1 wt % in Example 2-4. A second monomer is included in an amount of about 5 wt % in Example 2-5. A second monomer is included in an amount of about 10 wt % in Example 2-6.

Examples 3-4 to 3-6 were selected from the Example Group I. A second monomer is included in an amount of about 1 wt % in Example 3-4. S second monomer is included in an amount of about 5 wt % in Example 3-5, and a second monomer is included in an amount of about 10 wt % in Example 3-6.

Examples 4-4 to 4-6 were selected from the Example Group J. A second monomer is included in an amount of about 1 wt % in Example 4-4. A second monomer is included in an amount of about 5 wt % in Example 4-5. A second monomer is included in an amount of about 10 wt % in Example 4-6.

Examples 5-4 to 5-6 were selected from the Example Group K. A second monomer is included in an amount of about 1 wt % in Example 5-4. A second monomer is included in an amount of about 5 wt % in Example 5-5. A second monomer is included in an amount of about 10 wt % in Example 5-6.

Examples 6-4 to 6-6 were selected from the Example Group L. A second monomer is included in an amount of about 1 wt % in Example 6-4. A second monomer is included in an amount of about 5 wt % in Example 6-5. A second monomer is included in an amount of about 10 wt % in Example 6-6.

In FIG. 7B, Comparative Example 1-2 corresponds to Comparative Example Group C, and Comparative Example 2-2 corresponds to the Comparative Example Group D.

Referring to Table 4 and FIG. 7B, it can be seen that Examples 1-4 to 1-6, Examples 2-4 to 2-6, Examples 3-4 to 3-6, Examples 4-4 to 4-6, Examples 5-4 to 5-6, and Examples 6-4 to 6-6 have a higher photoconversion efficiency maintenance rate during the film formation processes than Comparative Example 1-2.

On the other hand, Comparative Example 2-2, which contained the antioxidant in a small amount, and thus exhibited a further excellent photoconversion maintenance rate than some Examples. However, as described above, it is confirmed that when the amount of the antioxidant included in Comparative Example 2-2 is excessively as high as the amount of the second monomer of Examples, the solubility of the antioxidant becomes poorer resulting in non-uniform single-film conditions, such as cracks occurring in the single film.

### 4) Preparation of Ink Compositions According to Example Groups M to R, and Comparative Example Groups E and F

Ink compositions according to Example Groups M to R, and Comparative Example Groups E and F were prepared by controlling the concentrations of the second monomers or antioxidants according to ingredients and contents listed in Table 5, and photoconversion efficiency maintenance rates of each Example Group and Comparative Example Group were listed in Table 6 (content unit:wt %). The photoconversion efficiency maintenance rates of Example Groups M to R, Comparative Example Groups E and F were measured in the same manner as those of Example Groups A to F, Comparative Example Groups A and B.

TABLE 5

| | | Comparative | Comparative | | | | | | |
|---|---|---|---|---|---|---|---|---|---|
| | | Example | Example | Example | Example | Example | Example | Example | Example |
| | | Group E | Group F | Group M | Group N | Group O | Group P | Group Q | Group R |
| Quantum | QD-1 | — | — | — | — | — | — | — | — |
| dot | QD-2 | — | — | — | — | — | — | — | — |
| | QD-3 | 40 | 40 | 40 | 40 | 40 | 40 | 40 | 40 |
| First | HDDA | 55 | 54.5/54/5 | 54/50/45 | 54/50/45/ | 54/50/45/ | 54/50/45/ | 54/50/45/ | 54/50/45/ |
| monomer | | | 0/45/35/ | /35/15 | 35/15 | 35/15 | 35/15 | 35/15 | 35/15 |
| | | | 15 | | | | | | |
| Second | Compound S1 | — | — | 1/5/10/ | — | — | — | — | — |
| monomer | | | | 20/40/ | | | | | |
| | Compound S2 | — | — | — | 1/5/10/ | — | — | — | — |
| | | | | | 20/40 | | | | |
| | Compound S3 | — | — | — | — | 1/5/10/ | — | — | — |
| | | | | | | 20/40 | | | |
| | Compound S4 | — | — | — | — | — | 1/5/10/ | — | — |
| | | | | | | | 20/40 | | |
| | Compound S5 | — | — | — | — | — | — | 1/5/10/ | — |
| | | | | | | | | 20/40 | |
| | Compound S6 | — | — | — | — | — | — | — | 1/5/10/ |
| | | | | | | | | | 20/40 |
| Antioxidant | | — | 0.5/1/5/ | — | — | — | — | — | — |
| | | | 10/20/40/ | | | | | | |
| Scatterer | TiO₂ | 4 | 4 | 4 | 4 | 4 | 4 | 4 | 4 |
| Initiator | TPO | 1 | 1 | 1 | 1 | 1 | 1 | 1 | 1 |

1) Example Group M: Examples M-1 to M-5
2) Example Group N: Examples N-1 to N-5
3) Example Group O: Examples O-1 to O-5
4) Example Group P: Examples P-1 to P-5
5) Example Group Q: Examples Q-1 to Q-5
6) Example Group R: Examples R-1 to R-5
7) Comparative Example Group E: Comparative Example E-1
8) Comparative Example Group F: Comparative Examples F-1 to F-6
Examples M-1, N-1, O-1, P-1, Q-1, and R-1, and Comparative Example F-2:
Examples M-2, N-2, O-2, P-2, Q-2, and R-2, and Comparative Example F-3: first monomer content of about 50 wt %, second monomer (or antioxidant) content of about 5 wt %
Examples M-3, N-3, O-3, P-3, Q-3, and R-3, and Comparative Example F-4: first monomer content of about 45 wt %, second monomer (or antioxidant) content of about 10 wt %
Examples M-4, N-4, O-4, P-4, Q-4, and R-4, and Comparative Example F-5: first monomer content of about 35 wt %, second monomer (or antioxidant) content of about 20 wt %
Examples M-5, N-5, O-5, P-5, Q-5, and R-5, and Comparative Example F-6: first monomer content of about 15 wt %, second monomer (or antioxidant) content of about 40 wt %
Comparative Example E-1: the first monomer content of about 55 wt %
Comparative Example F-1: first monomer content of about 54.5 wt %, antioxidant content of about 0.5 wt %
<Material>
QD-1: mPEG4-CH₃COOH is used, as a ligand, on a surface of quantum dot including InP core and ZnS shell
QD-2: mPEG4-CH₃COOH and mPEG5-SH are used as a ligand, by mixing at a molar ratio of 2:1, on a surface of quantum dot including InP core and ZnS shell InP
QD-3: mPEG4-CH₃COOH and mPEG5-SH are used, as a ligand by mixing at a molar ratio of 1:1, on a surface of quantum dot including InP core and ZnS shell InP
HDDA: 1,6-hexanediol diacrylate
Compounds S1 to S6: compounds S1 to S6 in Compound Group 1
TPO: 2,4,6-Trimethylbenzoyl-diphenyl phosphine oxide
Antioxidant: [2,2-bis[(2,6-ditert-butyl-4-methylphenoxy)methyl]-3-dihydroxyphosphanyloxypropyl] dihydrogen phosphite

TABLE 6

| | Content of antioxidant or second monomer | | | | | | |
|---|---|---|---|---|---|---|---|
| | 0 wt % | 0.5 wt % | 1 wt % | 5 wt % | 10 wt % | 20 wt % | 40 wt % |
| Comparative | 88.70% | — | — | — | — | — | — |
| Example Group E | | | | | | | |
| Comparative | — | 90.30% | Defect of single film condition | | | | |
| Example Group F | | | | | | | |
| Example Group M | — | — | 90.10% | 96.10% | 99.10% | 99.50% | 78.90% |
| Example Group N | — | — | 90.00% | 94.30% | 97.50% | 98.10% | 80.60% |
| Example Group O | — | — | 91.10% | 96.60% | 99.30% | 99.10% | 82.50% |
| Example Group P | — | — | 90.20% | 93.90% | 97.70% | 98.10% | 83.10% |
| Example Group Q | — | — | 90.50% | 94.00% | 96.90% | 96.50% | 81.50% |
| Example Group R | — | — | 89.90% | 95.10% | 96.40% | 97.30% | 80.70% |

1) Example Group M: average value of photoconversion efficiencies of Examples M-1 to M-5
2) Example Group N: average value of photoconversion efficiencies of Examples N-1 to N-5
3) Example Group O: average value of photoconversion efficiencies of Examples O-1 to O-5
4) Example Group P: average value of photoconversion efficiencies of Examples P-1 to P-5
5) Example Group Q: average value of photoconversion efficiencies of Examples Q-1 to Q-5
6) Example Group R: average value of photoconversion efficiencies of Examples R-1 to R-5
7) Comparative Example Group E: photoconversion efficiencies of Comparative Example E-1
8) Comparative Example Group F: average value of photoconversion efficiencies of Comparative Examples F-1 to F-6

Referring to Table 6, Example Groups M to R, in which include the quantum dot QD-3 and use the second monomer according to embodiments, have excellent chemical characteristics when—the second monomer is included in an amount in a range of about 1 wt % to about 40 wt %, thereby exhibiting a good level of photoconversion efficiency maintenance rate. It can be confirmed that, when the second monomer is included in the amount in a range of about 1 wt % to about 20 wt % in Example Groups M to R, the photoconversion efficiency maintenance rate is high even after the film formation processes (exposure, bake) are performed, compared to Comparative Example Group E.

The Comparative Example Group E, which contains the quantum dot QD-3, but contain neither the antioxidant nor the second monomer according to embodiments, exhibited a photoconversion efficiency maintenance rate of about 88.70%. Comparative Example Group F uses an antioxidant in a small amount of about 0.5 wt %, and thus exhibited an improved photoconversion efficiency maintenance compared to Comparative Example Group E. However, it was confirmed that when the amount of the antioxidant is greater than or equal to about 1 wt %, the solubility of the antioxidant becomes poorer, resulting in a non-uniform single-film conditions, such as cracks occurring in the single film.

The ink compositions of Example Groups M to R, which include the second monomers in an amount of about 1 wt %, about 5 wt %, and about 10 wt %, and have high photoconversion efficiency maintenance rates during processes were respectively sub-classified into Examples 1-7 to 1-9, 2-7 to 2-9, 3-7 to 3-9, 4-7 to 4-9, 5-7 to 5-9, and 6-7 to 6-9, and the photoconversion efficiency maintenance rates of these sub-classified Examples were measured during process. The measurement results are shown in a graph of FIG. 7C. In FIG. 7C, amounts of the antioxidant for each of Examples 1-7 to 1-9, Examples 2-7 to 2-9, Examples 3-7 to 3-9, Examples 4-7 to 4-9, Examples 5-7 to 5-9, and Examples 6-7 to 6-9 on the x-axis indicates the amounts of the second monomer.

Examples 1-7 to 1-9 are selected from the Example Group M, the second monomer is included in an amount of about 1 wt % in Example 1-7 the second monomer is included in an amount of about 5 wt % in Example 1-8, and the second monomer is included in an amount of about 10 wt % in Example 1-9.

Examples 2-7 to 2-9 are selected from the Example Group N, the second monomer is included in an amount of about 1 wt % in Example 2-7 the second monomer is included in an amount of about 5 wt % in Example 2-8, and the second monomer is included in an amount of about 10 wt % in Example 2-9.

Examples 3-7 to 3-9 are selected from the Example Group O, the second monomer is included in an amount of about 1 wt % in Example 3-7 the second monomer is included in an amount of about 5 wt % in Example 3-8, and the second monomer is included in an amount of about 10 wt % in Example 3-9.

Examples 4-7 to 4-9 are selected from the Example Group P, the second monomer is included in an amount of about 1 wt % in Example 4-7 the second monomer is included in an amount of about 5 wt % in Example 4-8, and the second monomer is included in an amount of about 10 wt % in Example 4-9.

Examples 5-7 to 5-9 are selected from the Example Group Q, the second monomer is included in an amount of about 1 wt % in Example 5-7 the second monomer is included in an amount of about 5 wt % in Example 5-8, and the second monomer is included in an amount of about 10 wt % in Example 5-9.

Examples 6-7 to 6-9 are selected from the Example Group R, the second monomer is included in an amount of about 1 wt % in Example 6-7 the second monomer is included in an amount of about 5 wt % in Example 6-8, and the second monomer is included in an amount of about 10 wt % in Example 6-9.

In FIG. 7C, Comparative Example 1-3 corresponds to the Comparative Example Group E, and Comparative Example 2-3 corresponds to the Comparative Example Group F.

Referring to Table 6 and FIG. 7C, it can be seen that most of Examples 1-7 to 1-9, Examples 2-7 to 2-9, Examples 3-7 to 3-9, and Examples 4-7 to Example 4-9, Example 5-7 to Example 5-9, and Example 6-7 to Example 6-9 have excellent photoconversion efficiency maintenance rate during the film formation processes compared to Comparative Examples 1-3 and 2-3.

### 5) Preparation of Ink Compositions According to Example Groups S to X, Comparative Example Groups G and H

Ink compositions according to Example Groups S to X, and Comparative Example Groups X and H were prepared according to the ingredients and contents listed in Table 7 below by controlling the content ratio of the second monomer or the antioxidant, and out-gas generation amounts of Example Groups and Comparative Example Groups were evaluated. The evaluation results were listed in Table 8 (content unit:wt %).

In Table 8, a single film was formed from the ink composition according to Examples and Comparative Examples, was inputted in a chamber and maintained at a temperature of greater than or equal to about 180° C. to measure a generation amount of out-gas through measuring a weight change, and the measurement results were listed as an evaluation result of the out-gas generation. In Table 8, the generation amount of out-gas was calculated from an increased amount with respect to the Comparative Example Group G.

TABLE 7

| | | Comparative | Comparative | | | | | | |
|---|---|---|---|---|---|---|---|---|---|
| | | Example | Example | Example | Example | Example | Example | Example | Example |
| | | Group G | Group H | Group S | Group T | Group U | Group V | Group W | Group X |
| Quantum | QD-2 | 40 | 40 | 40 | 40 | 40 | 40 | 40 | 40 |
| dot | | | | | | | | | |
| First | HDDA | 55 | 50/35/15 | 50/35/15/ | 50/35/15 | 50/35/15 | 50/35/15 | 50/35/15 | 50/35/15 |
| monomer | | | | | | | | | |
| Second | Compound S1 | — | | 5/20/40 | | | | | |
| monomer | Compound S2 | — | | | 5/20/40 | | | | |
| | Compound S3 | — | | | | 5/20/40 | | | |
| | Compound S4 | — | | | | | 5/20/40 | | |
| | Compound S5 | — | | | | | | 5/20/40 | |
| | Compound S6 | — | | | | | | | 5/20/40 |
| Antioxidant | | — | 5/20/40 | | | | | | |
| Scatterer | TiO₂ | 4 | 4 | 4 | 4 | 4 | 4 | 4 | 4 |
| Initiator | TPO | 1 | 1 | 1 | 1 | 1 | 1 | 1 | 1 |

1) Example Group S: Examples S-1 to S-3
2) Example Group T: Examples T-1 to T-3
3) Example Group U: Examples U-1 to U-3
4) Example Group V: Examples V-1 to V-3
5) Example Group W: Examples W-1 to W-3
6) Example Group X: Examples L-1 to L-3
7) Comparative Example Group G: Comparative Example G-1
8) Comparative Example Group H: Comparative Examples H-1 to H-3
Examples S-1, T-1, U-1, V-1, W-1, and X-1, and Comparative Example H-1: first monomer content of about 50 wt %, second monomer (or antioxidant) content of about 5 wt %
Examples S-2, T-2, U-2, V-2, W-2, and X-2, and Comparative Example H-2: first monomer content of about 35 wt %, second monomer (or antioxidant) content of about 20 wt %
Examples S-3, T-3, U-3, V-3, W-3, and X-3, and Comparative Example H-3: first monomer content of about 15 wt %, second monomer (or antioxidant) content of about 40 wt %
Comparative Example G-1: first monomer content of about 55 wt %
<Material>
QD-2: mPEG4-CH₃COOH and mPEG5-SH are used as a ligand by mixing at ratio of mPEG4-CH₃COOH:mPEGS-SH = 2:1 on surface of quantum dot including InP core and ZnS shell
HDDA: 1,6-hexanediol diacrylate
Compounds S1 to S6: compounds S1 to S6 in Compound Group 1
TPO: 2,4,6-trimethylbenzoyl-diphenyl phosphine oxide
Antioxidant: [2,2-bis[(2,6-ditert-butyl-4-methylphenoxy)methyl]-3-dihydroxyphosphanyloxypropyl] dihydrogen phosphite

TABLE 8

| | Content of antioxidant or second monomer | | | |
|---|---|---|---|---|
| | 0 wt % | 5 wt % | 20 wt % | 40 wt % |
| Comparative | 100.00% | — | — | — |
| Example Group G | | | | |
| Comparative | — | 103.20% | 110.50% | 129.70% |
| Example Group H | | | | |
| Example Group S | — | 101.10% | 102.00% | 105.50% |
| Example Group T | — | 100.50% | 100.90% | 104.70% |
| Example Group U | — | 100.70% | 103.10% | 106.10% |
| Example Group V | — | 101.60% | 102.50% | 102.90% |
| Example Group W | — | 102.00% | 103.70% | 103.90% |
| Example Group X | — | 100.10% | 103.10% | 105.40% |

1) Example Group S: average value of generation amounts of out-gas in Examples S-1 to S-3
2) Example Group T: average value of generation amounts of out-gas in Examples T-1 to T-3
3) Example Group U: average value of generation amounts of out-gas in Examples U-1 to U-3
4) Example Group V: average value of generation amounts of out-gas in Examples V-1 to V-3
5) Example Group W: average value of generation amounts of out-gas in Examples W-1 to W-3
6) Example Group X: average value of generation amounts of out-gas in Examples X-1 to X-3
7) Comparative Example Group G: generation amounts of out-gas in Comparative Example G-1
8) Comparative Example Group H: average value of generation amounts of out-gas in Comparative Examples H-1 to H-3

Referring to Table 8, it can be seen that Example Groups S to X, which include a second monomer, have smaller generation amount of out-gas than the Comparative Example Group G, which includes no second monomer, and Comparative Example Group H, which includes antioxidant.

From the above results, Example Groups S to X including a second monomer, in which an antioxidant is covalently bonded to an acrylate monomer have a small generation amount of out-gas during the high-temperature bake process in a temperature range of about 180° C. to about 220° C. Therefore, it can be seen that defects occurrence due to out-gas in a subsequent process may be reduced.

An ink composition according to an embodiment includes an antioxidant monomer, and thus even during an exposure process and a bake process for forming a light control layer, is excellent in a photoconversion efficiency maintenance rate. Therefore, out-gas generation may be reduced.

A display device according to an embodiment includes a light control layer formed by using the ink composition, and thus may exhibit improved reliability and excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. An ink composition comprising:
a quantum dot;
a first monomer that is an acrylate-based monomer;
a second monomer represented by Formula 1 or Formula 1-A;
a scatterer; and
an initiator: 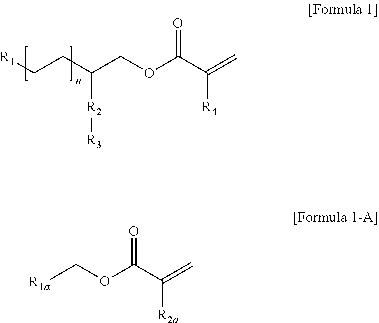
wherein in Formula 1,
R₁ is an acrylate group or a group represented by one of Formulas 2 to 4,
R₂ is a direct linkage or a substituted or unsubstituted divalent oxy group,
R₃ is a hydrogen atom or a group represented by one of Formulas 2 to 4,
R₄ is a hydrogen atom or a methyl group,
n is an integer from 0 to 10, and
one of R₁ and R₃ is a group represented by one of Formulas 2 to 4, and
wherein in Formula 1-A,
R₁ₐ is a group represented by one of Formulas 2 to 4, and
R₂ₐ is a hydrogen atom or a methyl group: 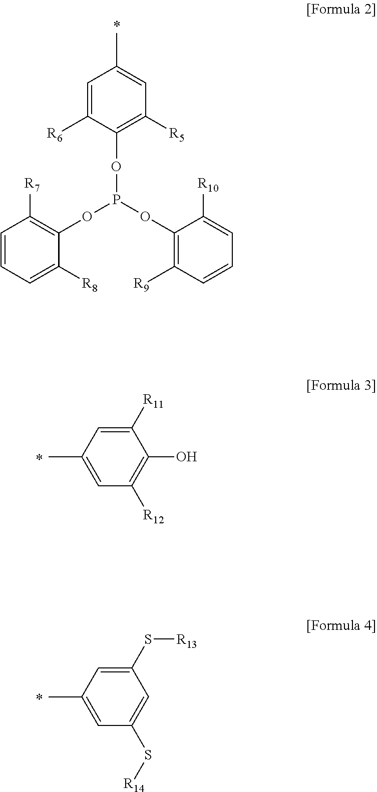
wherein in Formulas 2 and 3,
R₅ to R₁₂ are each independently a substituted or unsubstituted alkyl group having 1 to 10 carbon atoms, and
wherein in Formula 4,
R₁₃ and R₁₄ are each independently a substituted or unsubstituted alkyl group having 1 to 10 carbon atoms or a substituted or unsubstituted aryl group having 3 to 10 ring-forming carbon atoms.

2. The ink composition of claim 1, wherein
R₅ to R₁₀ are each independently a substituted or unsubstituted t-butyl group,
R₁₁ and R₁₂ are each independently a substituted or unsubstituted methyl group or a substituted or unsubstituted t-butyl group, and
R₁₃ and R₁₄ are each independently a substituted or unsubstituted n-butyl group.

3. The ink composition of claim 1, wherein the second monomer represented by Formula 1 is represented by Formula 1-1 or Formula 1-2: 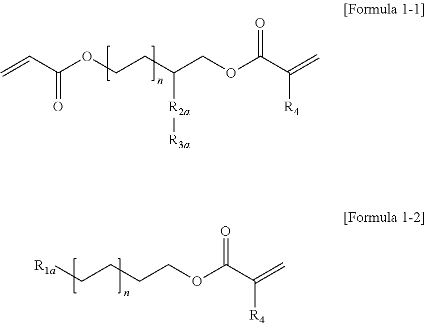
wherein in Formula 1-1,
R₂ₐ is a direct linkage or a substituted or unsubstituted divalent alkyloxy group having 1 to 10 carbon atoms, and
R₃ₐ is a group represented by one of Formulas 2 to 4,
wherein in Formula 1-2,
R₁ₐ is a group represented by one of Formulas 2 to 4, and
wherein in Formulas 1-1 and 1-2,
R₄ and n are each the same as defined in Formula 1.

4. The ink composition of claim 1, wherein the second monomer includes at least one compound selected from Compound Group 1:

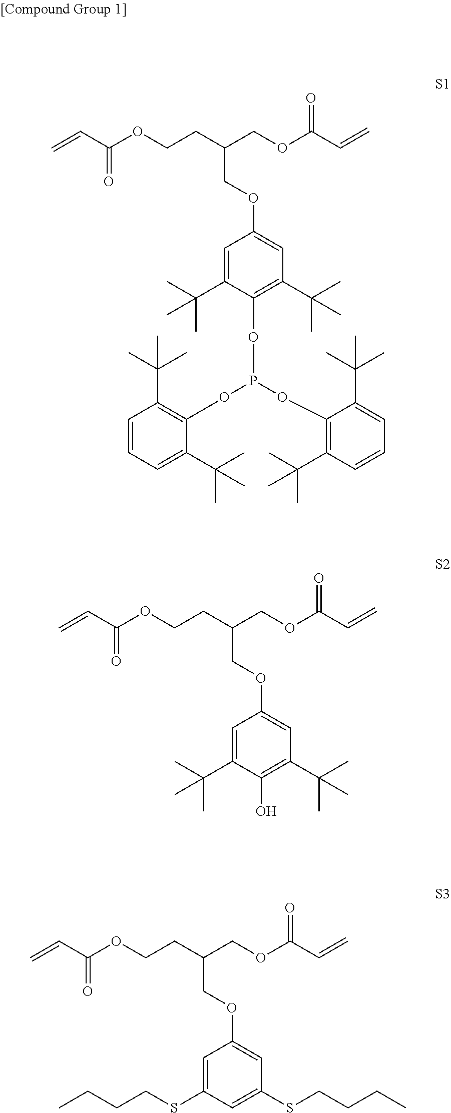

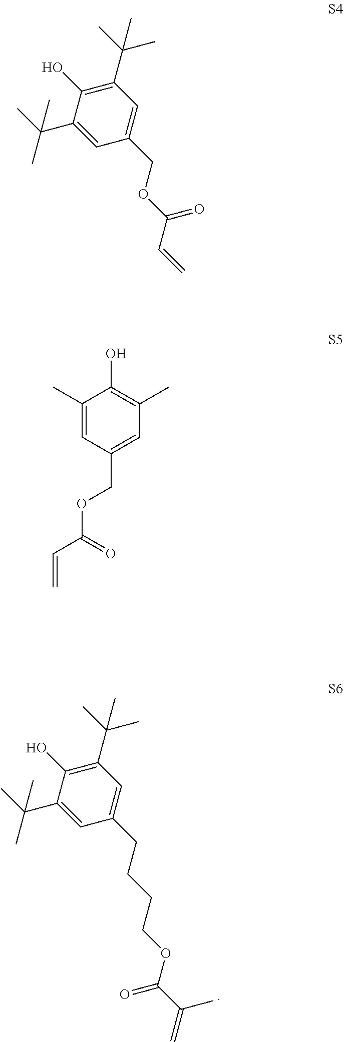

5. The ink composition of claim 1, wherein an amount of the second monomer is in a range of about 1 wt % to about 20 wt %, with respect to a total weight of the ink composition.

6. The ink composition of claim 1, wherein an amount of the quantum dot is in a range of about 30 wt % to about 50 wt %, with respect to a total weight of the ink composition.

7. The ink composition of claim 1, wherein the quantum dot includes:
a core; and
a shell covering the core.

8. The ink composition of claim 7, wherein the core includes InP.

9. The ink composition of claim 1, wherein the quantum dot further comprises a ligand bound to a surface of the quantum dot.

10. The ink composition of claim 9, wherein the ligand includes a thiol group (—SH) or a carboxylic acid group (—COOH).

11. The ink composition of claim 1, wherein the first monomer includes 1,6-hexanediol diacrylate.

12. The ink composition of claim 1, wherein the scatterer includes at least one of TiO₂, Al₂O₃, SiO₂, ZnO, ZrO₂, BaTiO₃, Ta₂O₅, Ti₃O₅, ITO, IZO, ATO, ZnO—Al, Nb₂O₃, SnO, and MgO.

13. A display device comprising:
a circuit element layer;
a display element layer disposed on the circuit element layer; and
a light control layer disposed on the display element layer and including a first light control part, a second light control part, and a third light control part that are spaced apart in a direction perpendicular to a thickness direction, wherein
the first light control part and the second light control part each include a quantum dot, a first monomer, a second monomer, and a scatterer,
the third light control part includes the first monomer and the scatterer, and
in the second monomer, a phosphorus-based antioxidant, a phenol-based antioxidant, or a sulfur-based antioxidant is bound to an acrylate-based monomer via a covalent bond.

14. The display device of claim 13, wherein the first monomer is an acrylate-based monomer.

15. The display device of claim 13, wherein the second monomer is represented by Formula 1 or Formula 1-A: 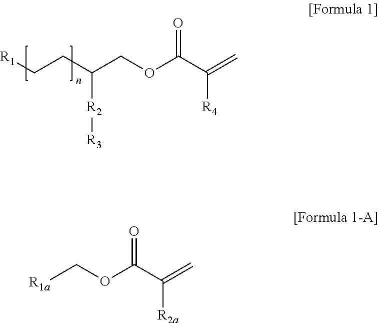
wherein in Formula 1,
R₁ is an acrylate group or a group represented by one of Formulas 2 to 4,
R₂ is a direct linkage or a substituted or unsubstituted oxy group,
R₃ is a hydrogen atom or a group represented by one of Formulas 2 to 4,
R₄ is a hydrogen atom or a methyl group,
n is an integer from 0 to 10, and
one of R₁ and R₃ is a group represented by one of Formulas 2 to 4, and
wherein in Formula 1-A,
R₁ₐ is a group represented by one of Formulas 2 to 4, and
R₂ₐ is a hydrogen atom or a methyl group: 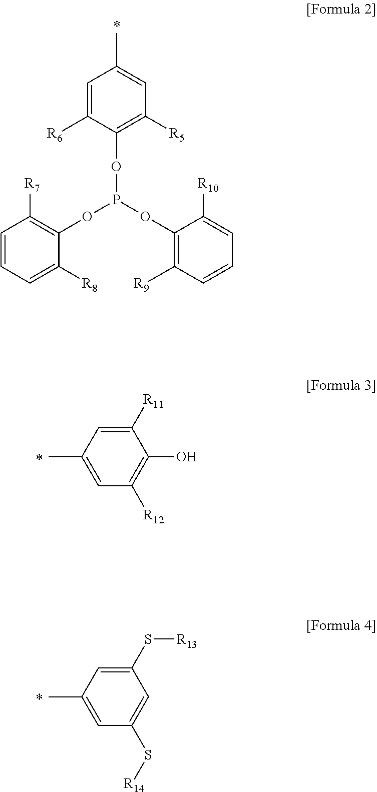
wherein in Formulas 2 and 3,
R₅ to R₁₂ are each independently a substituted or unsubstituted alkyl group having 1 to 10 carbon atoms, and
wherein in Formula 4,
R₁₃ and R₁₄ are each independently a substituted or unsubstituted alkyl group having 1 to 10 carbon atoms or a substituted or unsubstituted aryl group having 3 to 10 ring-forming carbon atoms.

16. The display device of claim 13, wherein the second monomer is represented by Formula 1-1 or Formula 1-2: 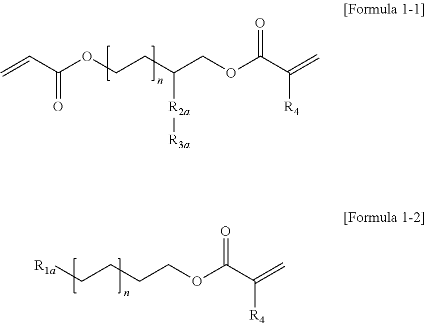
wherein in Formula 1-1,
R₂ₐ is a direct linkage or a substituted or unsubstituted divalent alkyloxy group having 1 to 10 carbon atoms, and
R₃ₐ is a group represented by one of Formulas 2 to 4,
wherein in Formula 1-2,
R₁ₐ is a group represented by one of Formulas 2 to 4, and
wherein in Formulas 1-1 and 1-2,
R₄ and n are each the same as defined in Formula 1.

17. The display device of claim 13, wherein, the second monomer includes at least one compound selected from Compound Group 1:

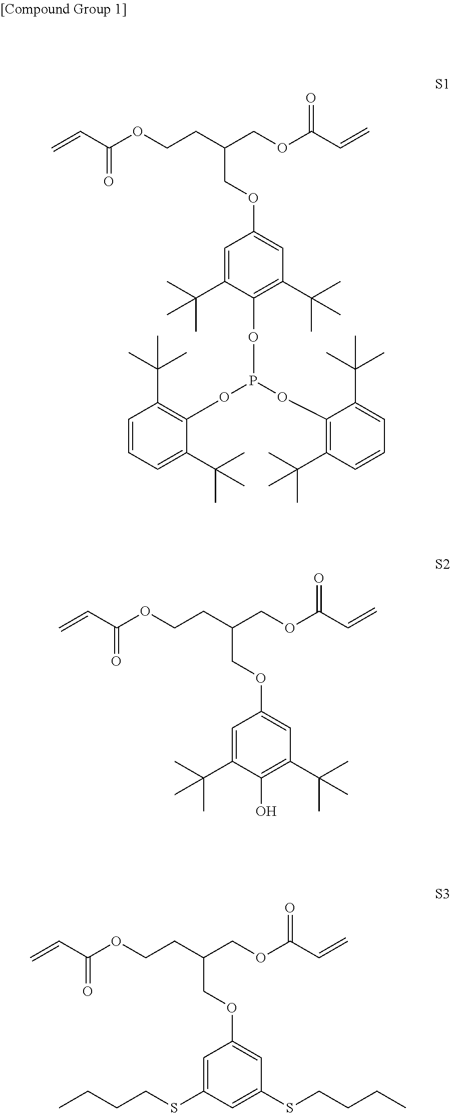

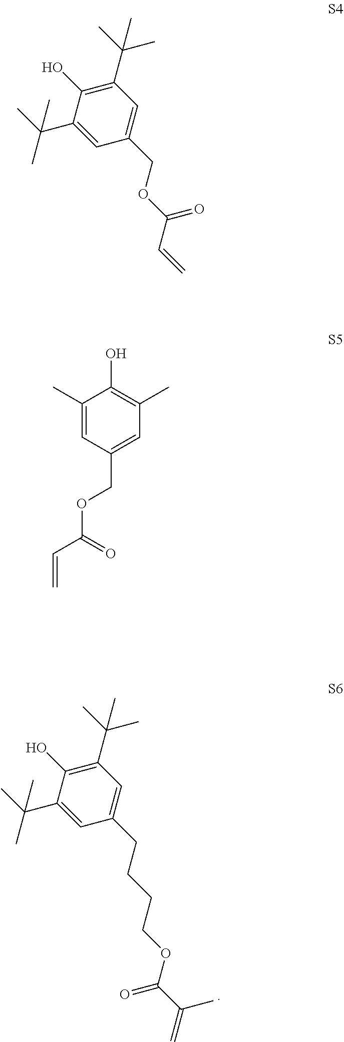

18. The display device of claim 13, further comprising:
a color filter layer disposed on the light control layer.

19. The display device of claim 18, wherein the color filter layer comprises a first filter, a second filter, and a third filter that respectively correspond to the first light control part, the second light control part, and the third light control part.

20. The display device of claim 19, wherein
the first to third light control parts are each parallel to the direction perpendicular to a thickness direction,
the first to third filters are each parallel to the direction perpendicular to a thickness direction, and
on a cross-section parallel to the thickness direction, a minimum width of each of the first to third light control parts is substantially the same as a minimum width of each of the first to third filters.
